(19) United States
(12) Patent Application Publication
(10) Pub. No.: US 2005/0082664 A1
(43) Pub. Date: Apr. 21, 2005

(54) Stacked semiconductor device and semiconductor chip control method

(75) Inventors: Seiji Funaba, Tokyo (JP); Yoji Nishio, Tokyo (JP)

Correspondence Address: MCGINN & GIBB, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 10/964,919

(22) Filed: Oct. 15, 2004

(30) Foreign Application Priority Data
Oct. 16, 2003 (JP) 2003-356689

(51) Int. Cl. H01L 23/495

(52) U.S. Cl. 257/724

(57) ABSTRACT

Each of stacked memory chips has an ID generator circuit for generating identification information in accordance with its manufacturing process. Since the memory chip manufacturing process implies process variations, the IDs generated by the respective ID generator circuits are different from one another even though the ID generator circuits are identical in design. A memory controller instructs an ID detector circuit to detect the IDs of the respective memory chips, and individually controls the respective memory chips based on the detected IDs.

### BACKGROUND OF THE INVENTION

1. Field of the Invention

The present invention relates to a semiconductor device and a semiconductor chip control method, and more particularly, to a stacked semiconductor device which has semiconductor chips such as memory chips stacked one upon another, and a method of controlling such semiconductor chips.

2. Description of the Related Art

It is anticipated that if the semiconductor manufacturing process encounters difficulties in miniatualization in the future, an increase in the size of chips associated with improvements on functions of LSI chips (for example, an increased storage capacity of DRAM) cannot be prevented by process-based miniatualization.

To cope with such a possible problem, a CoC (Chip on Chip) structure has been devised for semiconductor devices (for example, DRAM) which may includes LSI chips stacked one upon another for three-dimensionally expanding functions of the LSI chips (for example, the storage capacity of DRAM).

At present, there are a first and a second CoC structure contemplated for DRAM.

DRAM in the first CoC structure distinguishes stacked DRAM chips from one another as different ranks independent of one another.

DRAM in the second CoC structure regards the entire stacked DRAM chips as a single rank, and distinguishes the stacked chips from one another using different bank addresses within the same rank.

Stacking a single interface chip and a plurality of memory core chips may form the DRAM in the second CoC structure. The interface chip has interface functions of DRAM. The memory core chip in turn has memory core functions (a memory array and associated peripheral circuits).

The interface functions refer to such functions that are implemented, for example, by a data input output circuit, a control clock circuit, and an address buffer.

An exemplary interface function of DRAM involves converting a control signal or a data signal applied from the outside of the chip to an internal signal, and sending the internal signal to peripheral circuits of a memory array. Another exemplary interface function of DRAM involves fetching read data from the memory array to the peripheral circuits, and delivering the read data to the outside of the chip.

JP-6-291250-A discloses a semiconductor device in a CoC structure.

The semiconductor device in the CoC structure disclosed in JP-6-291250-A includes a different wiring pattern or circuit for each stacked chip.

Specifically, each of the stacked chips is associated with a different wiring pattern and circuit for generating an address that identifies the chip based on an address signal delivered from an address decoder. The wiring pattern and circuit will hereinafter be called the “address generation wiring pattern and address generator circuit.”

A different wiring pattern or circuit is associated with each of the stacked chips for the following reasons.

A plurality of chips which make up the CoC structure are electrically connected to one another via “through electrodes” having a diameter of approximately 10 microns, which extend through the plurality of chips. The through electrodes electrically short-circuit the plurality of stacked chips for connection. Therefore, the stacked chips receive the same signal, for example, a common address via the through electrodes.

Consequently, if stacked chips have formed thereon, for example, the same address generation wiring pattern and the same address generator circuit (for example, memory chips in the same configuration), one address signal specifies a plurality of chips in the same configuration. This can cause a problem that the plurality of chips performs the same operation.

To solve this potential problem, conventionally, chips stacked to make up the CoC structure differ from one another in wiring and circuits, as described in JP-6-291250-A, such that signal electrodes, formed at the same locations on the stacked chips, will not overlap in application, function and purpose.

JP-2002-50735-A also discloses a semiconductor device in a CoC structure. FIG. 1A is an explanatory diagram illustrating the semiconductor device in the CoC structure described in JP-2002-50735-A.

As illustrated in FIG. 1A, the front and back surfaces of first semiconductor chip 410 are connected via oblique through electrodes 417A, 417B, 417C which obliquely intersect with the front and back surfaces of semiconductor chip 410. Second and third semiconductor chips 420, 430, which have the same electrode structure, are stacked on first semiconductor chip 410.

First to third semiconductor chips 410, 420, 430 are connected to one another via oblique through electrodes 417A, 417B, 417C, 427A, 427B, 427C, 437A, 437B, 437C, and vertical through electrodes 418, 428, 438 or the like.

Protrusive electrode 415a transmits signals only to third semiconductor chip 430; protrusive electrode 415b to second semiconductor chip 420; and protrusive electrode 415c to first semiconductor chip 410.

Alternatively, even if the oblique through electrodes are not used as shown in FIG. 1A, similar functions to those of the semiconductor device illustrated in FIG. 1A can be implemented using a blind through hole structure which has through electrode 501 that is broken halfway in the semiconductor chip, as illustrated in FIG. 1B.

In FIG. 1B, semiconductor chip 510, semiconductor chip 520, and semiconductor chip 530 are stacked one upon another. Each semiconductor chip includes through electrode 501, pad 502, CS (chip select) terminal 504, wire 505, and throughhole 506. Pad 502 is pulled up or down by high resistor 503 for preventing voltage floating. CS terminal 504 receives chip select signals CS#1, CS#2, CS#3.

It is said, however, that if the blind throughhole structure is formed using a refractory metal such as titanium, tungsten or the like or a compound thereof in a chip which is manufactured using high-temperature processes, the resulting chip will not lend itself to micro-machining by dry etching, and will also imply a problem of corrosion after the etching.

The semiconductor device in the CoC structure described in JP-6-291250-A is disadvantageous in that when chips substantially identical in function (for example, memory chips) are stacked to complete the semiconductor device, it is necessary to prepare many types of chips different in wiring or circuit from one another equal to the number of chips to be stacked. Therefore, even though chips for use in building the semiconductor device are substantially identical in function, many types of chips must be manufactured and managed for inventory. This causes an increase in manufacturing steps.

On the other hand, when a semiconductor chip is formed with a through electrode which obliquely extends through the semiconductor chip, or when a semiconductor chip is formed with a blind throughhole structure, as the semiconductor device described in JP-2002-50735-A, a complicated manufacturing process is required. Disadvantageously, this will cause an increase in manufacturing cost.

### SUMMARY OF THE INVENTION

It is an object of the present invention to provide a semiconductor device which can employ a plurality of semiconductor chips in the same design that are stacked one upon another, without the need for complicated processes for obliquely passing through electrodes through the semiconductor chips or for forming a blind throughhole structure in each semiconductor chip.

To achieve the above object, a semiconductor device of the present invention includes a plurality of semiconductor chips, and a controller for controlling the plurality of semiconductor chips, wherein each of the plurality of semiconductor chips includes an identification information generator for generating identification information in accordance with the manufacturing process of the associated semiconductor chip, and the controller detects the identification information generated by the identification information generator in order to control each of the plurality of semiconductor chips based on the detected identification information.

According to the semiconductor device of the present invention, the identification information generator included in each of the semiconductor devices, generates the identification information in accordance with the manufacturing process of the semiconductor device. The semiconductor chip manufacturing process necessarily involves variations in manufacturing a plurality of semiconductor chips. Therefore, the respective identification information generators generate different identification information from one another even if a plurality of stacked semiconductor chips are identical in design.

Consequently, the controller can distinguish a plurality of semiconductor chips based on the identification information for individually controlling the semiconductor chips, even if the plurality of semiconductor chips are identical in design, and the controller provides a common signal to the plurality of semiconductor chips. This eliminates the need for modifying the design of semiconductor chips that have substantially the same functions in cases where that they are stacked one upon another.

It is also possible to eliminate a complicated process for passing through electrodes obliquely through the semiconductor chips or for forming a blind throughhole structure in the semiconductor chips.

Preferably, the semiconductor device described above further includes the following features.

The controller generates a plurality of chip select signals for alternatively selecting the plurality of semiconductor chips. Each of the plurality of semiconductor chips includes a chip select signal receiver that can be set to accept any of the plurality of chip select signals. The controller includes a setting unit for setting the chip select signal receiver based on the identification information such that the chip select signal receiver accepts a chip select signal for selecting a semiconductor chip which includes the chip select signal receiver, and a semiconductor chip controller for controlling each of the plurality of semiconductor chips based on the chip select signal.

According to the semiconductor device of the invention described above, the controller can control each of the plurality of semiconductor chips using the chip select signal.

Preferably, the chip select signal receiver is previously set to accept a particular chip select signal. With this setting, a semiconductor chip can be selected using a particular chip select signal before semiconductor chips are stacked. Therefore, for example, the semiconductor chip can be easily tested individually before the semiconductor chips are stacked.

The chip select signal receiver may include a switch, wherein the setting unit preferably sets the switch based on the identification information such that the chip select signal receiver accepts a chip select signal for selecting a semiconductor chip which includes the chip select signal receiver.

Alternatively, the chip select signal receiver may include a fuse, wherein the setting unit preferably controls the fuse based on the identification information such that the chip select signal receiver accepts a chip select signal for selecting a semiconductor chip which includes the chip select signal receiver. With this configuration, the fuse can permanently set the chip select signal receiver. It is therefore possible to prevent the same setting from being repeatedly made for the chip select signal receiver.

Each of the plurality of semiconductor chip may use its identification information as its chip address, wherein the controller may control each of the plurality of semiconductor chips based on the chip address. With this strategy, the controller can control each of the plurality of semiconductor chips using the chip address.

Also preferably, the semiconductor device described above includes the following features.

The controller generates a plurality of chip address signals for alternatively selecting the plurality of semiconductor chips. Each of the plurality of semiconductor chips includes a chip address signal receiver that can be set to accept any of the plurality of chip address signals. The controller includes a setting unit for setting the chip address signal receiver based on the identification information such that the chip address signal receiver accepts a chip address signal for selecting a semiconductor chip which includes the chip address signal receiver, and a semiconductor chip controller for controlling each of the plurality of semiconductor chips based on the chip address signal.

According to the semiconductor device of the invention described above, the controller can individually control each of the plurality of semiconductor chips using a plurality of the chip address signals for alternately selecting the plurality of semiconductor chips.

Preferably, the chip address signal receiver is previously set to accept a particular chip address signal. With this setting, a semiconductor chip can be selected using a particular chip address signal before semiconductor chips are stacked. Therefore, for example, the semiconductor chip can be readily tested alone before the semiconductor chips are stacked.

In addition, the chip address signal receiver may include a switch, wherein the setting unit preferably controls the switch based on the identification information such that the chip address signal receiver accepts a chip address signal for selecting a semiconductor chip which includes the chip address signal receiver.

Alternatively, the chip address signal receiver may include a fuse, wherein the setting unit preferably controls the fuse based on the identification information such that the chip address signal receiver accepts a chip address signal for selecting a semiconductor chip that includes the chip address signal receiver. With this configuration, the fuse can permanently set the chip address signal receiver. It is therefore possible to prevent the same setting from being repeatedly made for the chip select signal receiver.

Further preferably, the semiconductor device described above includes the following feature.

The plurality of semiconductor chips is interconnected by a through electrode that extends through the plurality of semiconductor chips, wherein the controller provides a common signal to the plurality of semiconductor chips via the through electrode.

Further preferably, the semiconductor device described above includes the following feature.

The plurality of semiconductor chips is interconnected through a bonding wire, wherein the controller provides a common signal to the plurality of semiconductor chips through the bonding wire.

Further preferably, the semiconductor device described above includes the following features.

The plurality of semiconductor chips make up packages together with boards on which the plurality of semiconductor chips are separately disposed. The packages are stacked one upon another.

The identification information generator preferably includes a self-running oscillator, and an identification information generator circuit for generating the identification information based on the output of the self-running oscillator. In this configuration, the self-running oscillators included in the respective semiconductor chips present shifted oscillation periods resulting from variations in the process for manufacturing the plurality of semiconductor chips. This permits the identification information generators to generate different identification information based on the outputs of the associated self-running oscillators, even if the respective semiconductor devices are identical in design.

The identification information generator circuit is preferably implemented by a counter for counting pulses generated by the self-running oscillator for a predetermined period of time, and for delivering the counted value as the identification information. With the use of the counter, a difference in the oscillation period of each self-running oscillator can be accumulated for the predetermined period of time to increase the difference in the oscillation period of each self-running oscillator.

Also, the identification information generator circuit may include a timer for measuring the predetermined period of time, wherein the counter preferably counts the pulses for the predetermined period of time based on the measured result of the timer.

The timer preferably divides the frequency of an external clock to measure the predetermined period of time. In this implementation, the identification information can be generated based on the difference in oscillation period between the respective self-running oscillators.

Also, the timer is preferably a self-running timer. In this implementation, the identification information can be generated based on the difference in oscillation period between the respective self-running oscillator and based on the difference in time measuring accuracy between the self-running timers.

The identification information generator circuit is preferably implemented by a shift register for sampling the pulses generated by the self-running oscillator based on a frequency-divided version of the external clock, and delivers the result of the sampling as the identification information.

Alternatively, the identification information generator circuit is preferably implemented by a shift register for circulating n-bit data that includes one bit having a different value from the remaining bits for a predetermined period of time based on the pulses generated by the self-running oscillator, and delivers the result of the circulation as the identification information.

Further, the identification information generator preferably has a predetermined initial value. In this implementation, the predetermined initial value may be used to select a semiconductor chip before semiconductor chips are stacked one upon another. Therefore, for example, each semiconductor chip can be readily tested alone before the semiconductor chips are stacked.

Preferably, each of the plurality of semiconductor chips is a memory chip. In this implementation, the resulting stacked memory can be comprised of stacked memory chips that are substantially identical in functions.

The plurality of semiconductor chips are preferably stacked one upon another.

According to another aspect of the present invention, a semiconductor chip control method is performed by a controller for controlling a plurality of semiconductor chips, wherein each of the plurality of semiconductor chips includes an identification information generator for generating identification information in accordance with its manufacturing process. The method includes a detecting step for detecting the identification information of each of the plurality of semiconductor chips, and a control step for controlling each of the plurality of semiconductor chips based on the identification information detected in the detecting step.

According to the method described above, the identification information generator included in each of the stacked semiconductor chips generates the identification information in accordance with the manufacturing process of the associated semiconductor chip. The semiconductor chip manufacturing process necessarily involves variations in manufacturing a plurality of semiconductor chips. Therefore, the respective identification information generators generate different identification information from one another even if a plurality of stacked semiconductor chips are identical in design.

Consequently, a plurality of semiconductor chips can be distinguished from one another based on the identification information for individually controlling the semiconductor chips even if the plurality of semiconductor chips are identical in design, and a common signal is provided to the plurality of semiconductor chips. This eliminates the need for modifying the design of semiconductor chips that have substantially the same functions when they are stacked one upon another.

It is also possible to eliminate a complicated process for passing through electrodes obliquely through the semiconductor chips or forming a blind throughhole structure in each semiconductor chip.

Preferably, the foregoing semiconductor chip control method further includes a setting step and a semiconductor chip control step.

Each of the plurality of semiconductor chips further includes a chip select signal receiver that can be set to accept any of a plurality of chip select signals generated by the controller. The setting step includes setting the chip select signal receiver based on the identification information such that the chip select signal receiver accepts a chip select signal for selecting a semiconductor chip which includes the chip select signal receiver. The semiconductor chip control step includes controlling each of the plurality of semiconductor chips based on the chip select signal. With this strategy, a plurality of semiconductor chips can be individually controlled using the chip select signals.

Preferably, each of the plurality of semiconductor chips uses its identification information as its chip address, wherein the detecting step includes detecting the chip address of each of the plurality of semiconductor chips, and the control step includes controlling each of the plurality of semiconductor chips based on the chip address detected in the detecting step.

Each of the plurality of semiconductor chips may include a chip address signal receiver which can be set to accept any of a plurality of chip address signals generated by the controller, wherein the method preferably includes a setting step for setting the chip address signal receiver based on the identification information such that the chip address signal receiver accepts a chip address signal for selecting a semiconductor chip which includes the chip address signal receiver, and a semiconductor chip control step for controlling each of the plurality of semiconductor chips based on said chip address signal. With this strategy, the plurality of semiconductor chips can be individually controlled using the chip address signals.

According to the present invention, even if a plurality of semiconductor chips identical in design are connected through electrodes involved in the same functions, as in stacked memory of CoC structure, the controller can distinguish each semiconductor chip for accessing an intended one. This is because each semiconductor chip includes the identification information generator.

The identification information generator can generate different identification information for each of the semiconductor chips, even though they are identical in design, for the reason set forth below.

The identification information generator generates the identification information, for example, using a self-running oscillator that generates an output in accordance with the manufacturing process of an associated semiconductor chip. The oscillation periods of the self-running oscillators differ from one another due to variations in the process for manufacturing the respective semiconductor chips. Further, for example, the difference in the oscillation period may be increased.

In addition, it is also possible to eliminate the complicated process for passing through electrodes obliquely through the semiconductor chips or forming a blind through structure in each semiconductor chip.

The above and other objects, features, and advantages of the present invention will become apparent from the following description with reference to the accompanying drawings which illustrate examples of the present invention.

### BRIEF DESCRIPTION OF THE DRAWINGS

FIG. 1A is an explanatory diagram illustrating conventional stacked semiconductor chips;

FIG. 1B are an explanatory diagram illustrating other conventional stacked semiconductor chips;

FIG. 2 is a block diagram illustrating a semiconductor memory device according to one embodiment of the present invention;

FIG. 3 is a block diagram illustrating an example of an ID generator circuit shown in FIG. 2;

FIG. 4 is a circuit diagram representing an example of the semiconductor memory device illustrated in FIG. 2;

FIG. 5 is a flow chart for describing the operation of the semiconductor memory device represented in FIG. 4;

FIG. 6 is a block diagram illustrating another example of the ID generator circuit shown in FIG. 2;

FIG. 7 is a block diagram illustrating a further example of the ID generator circuit shown in FIG. 2;

FIG. 8 is a block diagram illustrating another example of the semiconductor memory device;

FIG. 9 is a block diagram illustrating an example of an ID circuit shown in FIG. 8;

FIG. 10 is a circuit diagram representing an example of the semiconductor memory device illustrated in FIG. 8;

FIG. 11 is a circuit diagram representing an example of an ID detection completion determining circuit included in the semiconductor memory device illustrated in FIG. 8;

FIG. 12 is a flow chart for describing the operation of the semiconductor memory device represented in FIG. 10;

FIG. 13 is a block diagram illustrating another example of the semiconductor memory device;

FIG. 14 is a circuit diagram representing an example of the semiconductor memory device illustrated in FIG. 13;

FIG. 15A is an explanatory diagram illustrating another exemplary stack of semiconductor chips;

FIG. 15B is an explanatory diagram illustrating a further exemplary stack of semiconductor chips;

FIG. 16 is a circuit diagram representing an exemplary switch based on an electric fuse; and

FIG. 17 is a circuit diagram representing an exemplary default setting for selecting a semiconductor chip.

### DETAILED DESCRIPTION OF THE PREFERRED EMBODIMENTS

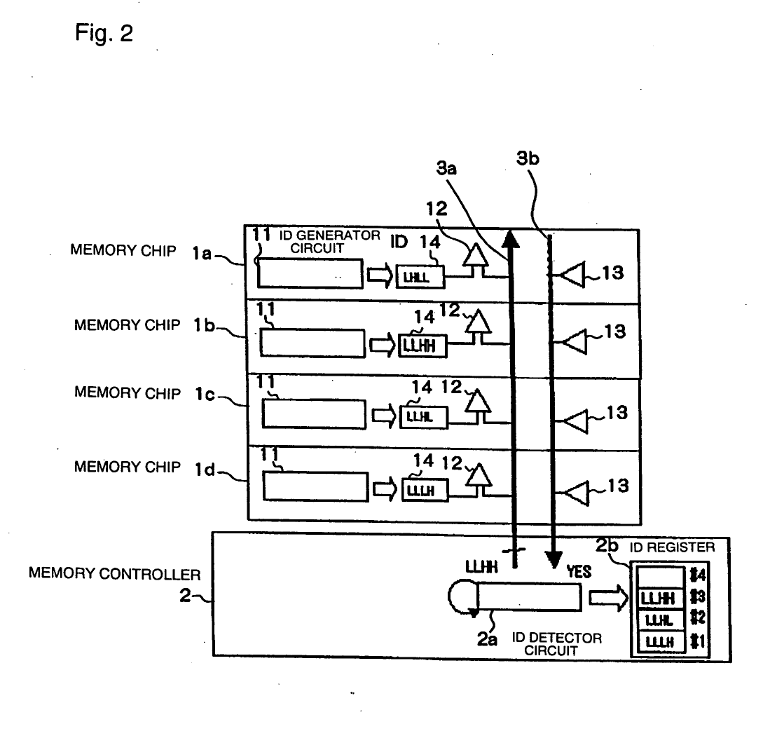

FIG. 2 is an explanatory diagram illustrating the basic configuration of a semiconductor memory device. The semiconductor memory device illustrated in FIG. 2 is an exemplary semiconductor device according to one embodiment of the present invention. It should be noted that the semiconductor device is not limited to the semiconductor memory device, but may be changed as appropriate.

In FIG. 2, the semiconductor memory device includes memory chips 1a-1d, and memory controller 2. Memory chips 1a-1d are examples of semiconductor chips. It should again be noted that semiconductor chips are not limited to memory chips but may be changed as appropriate. Memory controller 2 is an example of a controller.

Memory chips 1a-1d are stacked one upon another. The number of memory chips is not limited to four but may be changed as appropriate. Also, memory chips 1a-1d may or may not be stacked on memory controller 2.

Each of memory chips 1a-1d is formed in a common design. Therefore, circuits formed on respective memory chips 1a-1d are identical in design. Also, the circuits formed on respective memory chips 1a-1d are identical in layout. Further, the wires routed on respective memory chips 1a-1d are identical in design. In other words, in this embodiment, the design concept is such that the pattern of the memory chip is not modified depending on the order in which the memory chip is stacked.

Each of memory chips 1a-1d is formed with through electrodes 3 at the same locations on the memory chip. Each through electrode 3 is a throughhole type electrode that extends through the entire thickness of the chip. In this embodiment, each of memory chips 1a-1d is formed with a plurality of through electrodes 3.

Through electrodes 3 are electrically connected to associated throughhole electrodes 3 on the memory chips that are stacked above and/or below each other. A plurality of electrically connected through electrodes 3 form a through electrode bus. The through electrode bus is electrically connected to memory controller 2.

In this embodiment, through electrode 3a and through electrode 3b are used as through electrodes 3. Through electrode 3a receives an ID signal delivered from memory controller 2. Through electrode 3b receives an ID match signal delivered from each of memory chips 1a-1d.

Each of memory chips 1a-1d includes ID generator circuit 11, comparator 12, and ID match signal generator circuit 13. Each ID generator circuit 11, each comparators 12, and each ID match signal generator circuits 13 are identical in design regardless of the memory chip on which they are included. Therefore, the following description will focus on ID generator circuit 11, comparator 12, and ID match signal generator circuit 13 disposed on memory chip 1a, with omission of description on ID generator circuits 11, comparators 12, and ID match signal generator circuits 13 disposed on memory chips 1b-1d.

ID generator circuit 11 generates ID (identification information indicative of itself 14 of the memory chip on which ID generator circuit 11 is disposed. Specifically, ID generator circuit 11 generates ID 14 in accordance with its manufacturing process. This permits respective ID generator circuits 11 to generate different IDs 14 from one another, even if ID generator circuits 11 are identical in design, relying on variations in the process of respective ID generator circuits 11, and further relying on variations in the process of respective semiconductor chips 1a-1d.

Comparator 12 compares an ID signal provided thereto from memory controller 2 via through electrode 3a with ID 14. The ID signal is provided for detecting identification information (ID 14).

ID match signal generator circuit 13 delivers an ID match signal to through electrode 3b when comparator 12 generates an output that indicates that ID 14 matches the ID signal.

Memory controller 2 includes ID detector circuit 2a and ID register 2b. ID detector circuit 2a detects IDs 14 of respective stacked memory chips 1a-1d. Specifically, ID detector circuit 2a generates a plurality of types of ID signals. ID detector circuit 2a provides memory chips 1a-1d with the plurality of type ID signals one by one in order via through electrode 3a. As ID detector circuit 2a receives an ID match signal via through electrode 3b when it has delivered a certain ID signal, ID detector circuit 2a stores the ID signal in ID register 2b. Thus, ID register 2b stores IDs 14 of respective memory chips 1a-1d.

Memory controller 2 distinguishes respective memory chips 1a-1d from one another using the ID signal stored in ID register 2b, i.e., ID 14 of each memory chip 1a-1d, for access to each memory chip 1a-1d.

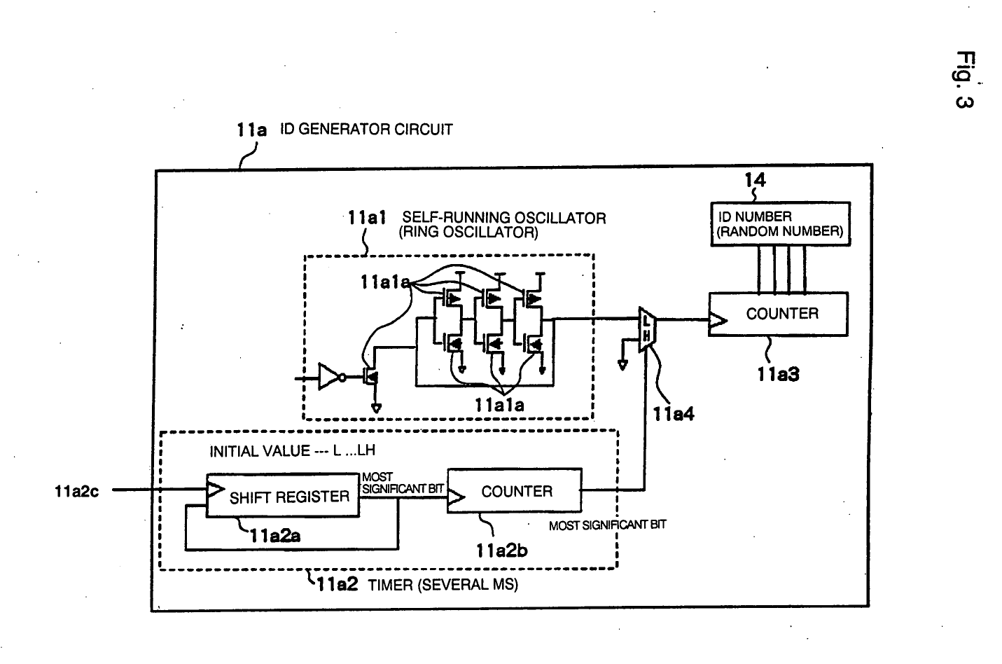

FIG. 3 is a block diagram illustrating a first embodiment of ID generator circuit 1 shown in FIG. 2. In FIG. 3, components identical to those shown in FIG. 2 are designated with the same reference numerals.

In FIG. 3, ID generator circuit 11a includes ring oscillator (self-running oscillator) 11a1, timer 11a2, counter 11a3, and selector 11a4. Ring oscillator 11a1 generates a high frequency signal (at a pulse period of several ns). Ring oscillator 11a1 includes a plurality of transistors 11a1a. Timer 11a2 generates a time-up signal at intervals of several microseconds. Counter 11a3 counts the number of pulses delivered from ring oscillator 11a1. Selector 11a4, responsive to the time-up signal generated by timer 11a2, forces ring oscillator 11a1 to stop supplying its output to counter 11a3, thereby stopping the counting of counter 11a3.

ID generator circuit 11a defines ID 14 as indicated by the counted value on counter 11a3 at this time.

Each of the stacked memory chips 1a-1d can be associated with variations in the process. Therefore, respective ring oscillators 11a1 slightly differ in the pulse period (approximately several microseconds) from one another due to the variations in the process.

Counter 11a3 counts the number of pulses that are generated by ring oscillator 11a1 for a longer time (approximately several microseconds) than the pulse period. This results in an increased difference between counted values of respective counters 11a3. This facilitates the generation of different IDs among the memory chips.

It should be noted that because transistor 11a1a is designed to be smaller, the variations in the process have more effect on the pulse period of ring oscillator 11a1. For this reason, different IDs can be more readily generated among the memory chips because transistor 11a1a is designed to be smaller.

Timer 11a2 includes a shift register 11a2a having a long bit length and counter 11a2b. Timer 11a2 is a circuit for dividing the frequency of external clock 11a3c by shift register 11a2a and counter 11a2b.

The initial value of shift register 11a2a consists of one bit set at “H” and the remaining bits set at “L.” In shift register 11a2a, the output of the most significant bit (trailing bit) is connected to the input of the least significant bit (front end bt). Data in shift register 11a2a is shifted at a rising timing of external clock 11a2c or at a falling timing of external clock 11a2c. The output of the most significant bit (rear end bit) of shift register 11a2a is applied to counter 11a2b. The most significant bit of counter 11a2b serves as the output of timer 11a2.

Timer 11a2 divides the frequency of external clock 11a2c to make a period of several microseconds. Thus, the period of timer 11a2 is set based on external clock 11a2c. As such, the period of timer 11a2 will not vary due to the process of the memory chip that contains timer 11a2.

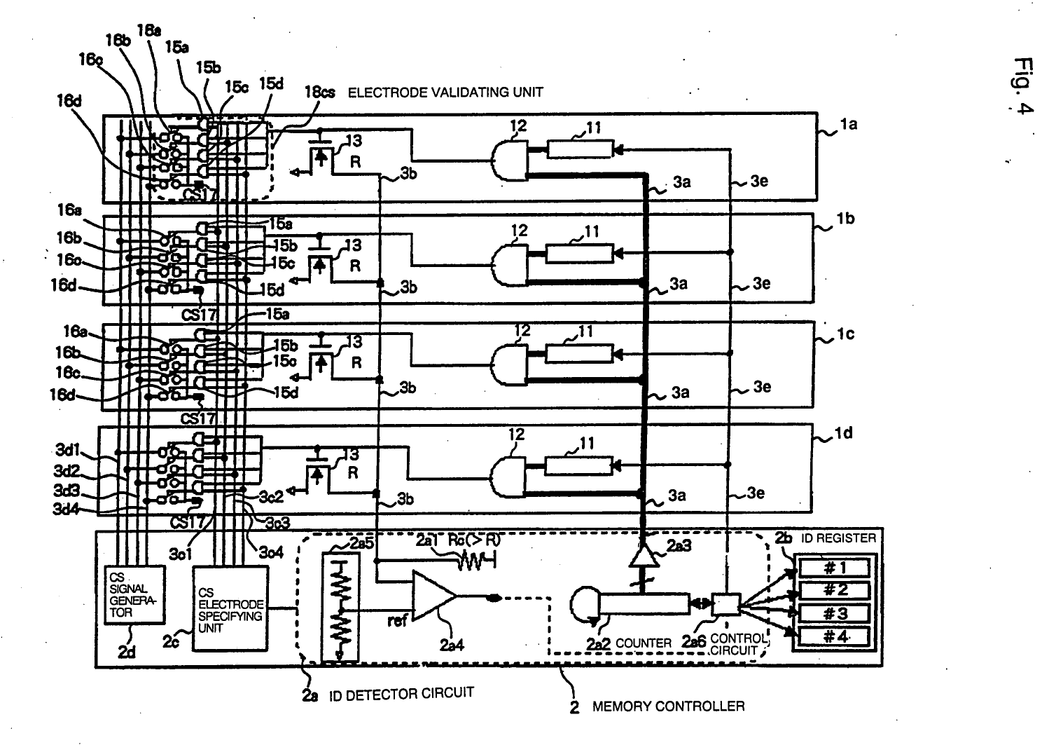

FIG. 4 is a circuit diagram representing a first embodiment of the semiconductor memory device illustrated in FIG. 2. Components in FIG. 4 identical to those in FIG. 2 are designated with the same reference numerals.

In FIG. 4, each of the memory chips 1a-1d includes ID generator circuit 11, comparator 12, ID match signal generator circuit 13, gate circuits 15a-15d, CS (chip select) switches 16a-16d serving as chip select signal receivers, CS signal wire 17, through electrode (through electrode bus) 3a, through electrode (through electrode bus) 3b, through electrodes 3c1-3c4 for CS electrode specifying signals, CS through electrodes 3d1-3d4, and through electrode 3e for an ID generation start signal.

Each of the memory chips 1a-1d includes CS electrode validating unit 18 for validating CS switches 16a-16d. CS switches 16a-16d may be implemented, for example, by electric fuses, or the like.

In this embodiment, both the ID and ID signals are 4-bit data. However, the ID and ID signals are not limited to 4-bit data, but may be modified as appropriate.

Since memory chips 1a-1d are identical in design, the following description will focus on memory chip 1a, with omission of description on memory chips 1b-1d.

Through electrode 3a and the output terminal of ID generator circuit 11 are connected to input terminals of comparator 12. The output of comparator 12 is connected to ID match signal generator circuit 13.

ID match signal generator circuit 13 comprises an open drain type transistor. ID match signal generator circuit 13 has a source connected to pull-up resistor 2a1 in memory controller 2 via through electrode 3b. Wired OR logic is made up of the output of ID match signal generator circuit 13 and the outputs of ID match signal generator circuits 13 of the other memory chips.

CS through electrodes 3d1-3d4 are each connected to memory controller 2. CS through electrodes 3d1-3d4 can be connected to CS signal wire 17 via any of CS switches 16a-16d.

Memory controller 2 selects an appropriate switch from CS switches 16a-16d and validates (turns on) selected CS switch 16, in order to avoid selecting two or more CS switches on memory chips 1a-1d, causing CS signal wire 17 to be directly connected to memory controller 2 via through electrode 3d that corresponds to the validated CS switch 16.

As a CS signal is supplied from memory controller 2 to CS signal wire 17 via CS through electrode 3d and CS switch 16, the CS signal activates a memory chip which contains CS signal wire 17 that is applied with the CS signal.

Memory controller 2 includes ID detector circuit 2a, ID register 2b, CS electrode specifier 2c, and CS signal source 2d. CS signal specifier 2c is an example of a setting unit. CS signal source 2d is an example of a semiconductor chip controller.

ID detector circuit 2a includes pull-up resistor 2a1, counter 2a2, output circuit 2a3, comparator 2a4, reference voltage generator 2a5, and control circuit 2a6. Counter 2a2 delivers a counted value (four bits) as an ID signal. Specifically, counter 2a2 increments its counted value from “LLLL” to “HHHH.” Counter 2a2 delivers the counted value to output circuit 2a3 in sequence. Output circuit 2a3 delivers the ID signal to through electrode 3a.

Each of the memory chips 1a-1d delivers an ID match signal to through electrode 3b when its own ID matches the ID signal supplied from through electrode 3a. Specifically, when its own ID matches the ID signal, comparator 12 generates a match output. As comparator 12 generates the match output, ID match signal generator circuit 13 delivers an ID match signal to through electrode 3b. It should be noted that in this embodiment, ID match signal generator circuit 13 and pull-up resistor 2a1 are placed in a relationship represented by R<Rc, where R is the output resistance of ID match signal generator circuit 13, and Rc is the resistance of pull-up resistor 2a1.

Comparator 2a4 compares voltage on through electrode 3b with voltage ref generated by reference voltage generator 2a5 (one-half of the pull-up voltage), to detect whether the ID match signal is supplied to through electrode 3b. Specifically, comparator 2a4 determines that the ID match signal is supplied to through electrode 3b when the voltage on through electrode 3b is lower than voltage ref. The ID match signal is generated when the ID of any memory chip “matches” the ID signal.

When comparator 2a4 detects that the ID match signal is supplied to through electrode 3b, control circuit 2a6 stores the counted value (ID) of counter 2a2 at that time in ID register 2b.

CS electrode specifier 2c is connected to through electrodes 3c1-3c4 for CS electrode specifying signal. CS electrode specifier 2c supplies a CS electrode specifying signal to through electrodes 3c1-3c4 for the CS electrode specifying signal to specify arbitrary CS switch 16 from among CS switches 16a-16d.

Memory controller 2 selects CS switch 16 that corresponds to an arbitrary one of CS through electrodes 3d1-3d4 contained in respective memory chips 1a-1d, using the ID of each memory chip 1a-1d and CS electrode specifier 2c, and validates the selected CS switch 16. An electric fuse or a latch circuit can implement CS switch 16.

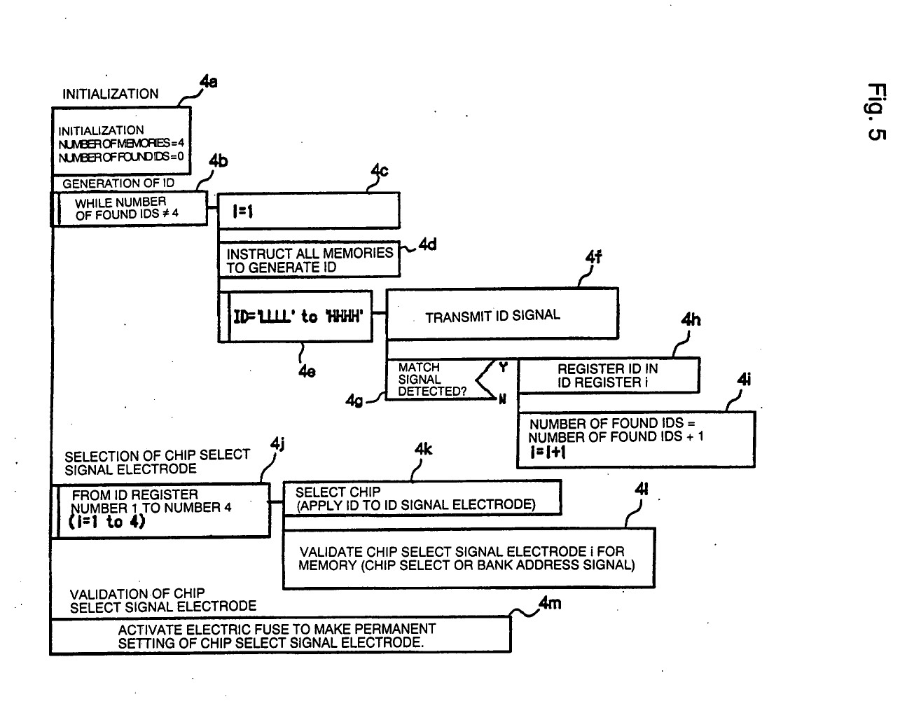

FIG. 5 is a flow chart for describing the operation of the first embodiment of the semiconductor memory device illustrated in FIG. 4. In the following, the operation of the first embodiment of the semiconductor memory device will be described with reference to FIG. 5.

At step 4a, memory controller 2, specifically control circuit 2a6, performs initialization for setting the number of stacked memory chips to “4” and the number of found IDs to “0.”

After completion of step 4a, memory controller 2, specifically control circuit 2a6, executes step 4b. At step 4b, memory controller 2, specifically, control circuit 2a6 repeats the ID detection processing shown below if the number of found IDs does not meet “4” which is the number of stacked memories (step 4c-step 4i).

As step 4c, control circuit 2a6 sets 1 to i (i=1) in a memory built therein, where i indicates a register number of ID register 2b. In this embodiment, ID register 2b includes four registers labeled register numbers 1-4.

Control circuit 2a6 executes step 4d after completion of step 4c. At step 4d, control circuit 2a6 instructs all memory chips 1a-1d to generate the ID. Specifically, control circuit 2a6 delivers an ID generation start signal to each ID generator circuit 11. The ID generation start signal is supplied to each ID generator circuit 11 via through electrode 3e. Each ID generator circuit 11 starts operating in response to the ID generation start signal applied thereto to generate ID 14.

Control circuit 2a6 executes step 4e after completion of step 4d. At step 4e, controller 2a6 instructs counter 2a2 to generate ID signals for all combinations from “LLLL” to “HHHH” in sequence. Each time counter 2a2 generates an ID signal, output circuit 2a3 executes step 4f. At step 4f, each time counter 2a2 generates an ID signal, output circuit 2a3 transmits the ID signal to each memory chip 1a-1d via through electrode 3a.

While output circuit 2a3 is transmitting the ID signals from “LLLL” to “HHHH,” control circuit 2a6 executes step 4g. At step 4g, control circuit 2a6 determines whether or not an ID match signal is generated from any of memory chips 1a-1d based on the output of comparator 2a4. When the ID match signal is delivered from any of memory chips 1a-1d, control circuit 2a6 executes step 4h. At step 4h, control circuit 2a6 registers the ID (the counted value of counter 2a2) at the time the ID match signal is delivered, in a register labeled register number i (starting from ID register number equal to one) of ID register 2b.

Control circuit 2a6 executes step 4i upon completion of step 4h. At step 4i, control circuit 2a6 increments the number of found IDs and i by one. Control circuit 2a6 executes step 4g upon completion of step 4i.

Control circuit 2a6 will detect a problem that a plurality of memory chips have the same ID if the number of found IDs has not reached “4” when the counted value of counter 2a2, i.e., the ID signal indicates “HHHH.” In this event, control circuit 2a6 returns the operation to step 4e, and instructs output circuit 2a3 to again transmit ID signals for all combinations from “LLLL” to “HHHH” to respective memory chips 1a-1d via through electrode 3a, and executes similar processing as in the foregoing.

Control circuit 2a6 proceeds to next CS validation processing if the number of found IDs has reached “4” when the counted value of counter 2a2, i.e., the ID signal, indicates “HHHH.”

Control circuit 2a6 uses the ID stored in the register labeled register number 1 of ID register 2b to select a memory chip corresponding to this ID. Then, control circuit 2a6 selects CS switch 16a corresponding to CS through electrode 3d1 that is contained in the selected memory chip. Specifically, control circuit 2a6 reads the ID stored in the register labeled register number 1 of ID register 2b, and delivers the read ID to through electrode 3a via output circuit 2a3. In a memory chip which has the same ID as the ID stored in the register labeled register number 1 of ID register 2b, comparator 12 delivers the output at “H,” causing gate circuits 15a-15d to open. In this embodiment, this condition is established when control circuit 2a6 has selected a memory chip corresponding to the ID stored in the register labeled register number 1 of ID register 2b.

Subsequently, CS electrode specifier 2c applies a signal, for specifying CS electrode 3d1 and that turns on CS switch 16a that corresponds to CS through electrode 3d1, to through electrodes for CS electrode specifying signal 3c1. This signal for specifying CS electrode 3d1 passes through gate circuit 15a contained in the memory chip corresponding to the ID stored in the register labeled register number 1 of ID register 2b, and selects CS switch 16a.

Thus, CS signal wire 17, contained in the memory chip corresponding to the ID stored in the register labeled register number 1 of ID register 2b, can be set such that CS signal wire 17 is applied with the CS signal which is supplied to CS through electrode 3d1.

Next, control circuit 2a6 uses the ID stored in the register labeled register number 2 of ID register 2b to select a memory chip corresponding to this ID. Control circuit 2a6 selects CS switch 16b corresponding to CS through electrode 3d2 of the selected memory chip. Specifically, control circuit 2a6 reads the ID stored in the register labeled register number 2 of ID register 2b, and delivers the read ID to through electrode 3a via output circuit 2a3. In the memory chip having the same ID as the ID stored in the register labeled register number 2 of ID register 2b, comparator 12 delivers the output at “H,” causing gate circuits 15a-15d to open. In this embodiment, this condition is established when control circuit 2a6 has selected a memory chip corresponding to the ID stored in the register labeled register number 2 of ID register 2b.

Subsequently, CS electrode specifier 2c applies a signal for specifying CS electrode 3d2 and that turns on CS switch 16b that corresponds to CS through electrode 3d2, to through electrodes for CS electrode specifying signal 3c2. This signal for specifying CS electrode 3d2 passes through gate circuit 15b contained in the memory chip corresponding to the ID stored in the register labeled register number 2 of ID register 2b, and selects CS switch 16b.

Thus, CS signal wire 17, contained in the memory chip corresponding to the ID stored in the register labeled register number 2 of ID register 2b, can be set such that CS signal wire 17 is applied with the CS signal which is supplied to CS through electrode 3d2.

Next, control circuit 2a6 uses the ID stored in the register labeled register number 3 of ID register 2b to select a memory chip corresponding to this ID. Control circuit 2a6 selects CS switch 16c corresponding to CS through electrode 3d3 of the selected memory chip. Specifically, control circuit 2a6 reads the ID stored in the register labeled register number 3 of ID register 2b, and delivers the read ID to through electrode 3a via output circuit 2a3. In the memory chip having the same ID as the ID stored in the register labeled register number 3 of ID register 2b, comparator 12 delivers the output at “H,” causing gate circuits 15a-15d to open. In this embodiment, this condition is established when control circuit 2a6 has selected a memory chip corresponding to the ID stored in the register labeled register number 3 of ID register 2b.

Subsequently, CS electrode specifier 2c applies a signal for specifying CS electrode 3d3 and that turns on CS switch 16c corresponding to CS through electrode 3d3, to through electrodes for CS electrode specifying signal 3c3.

This signal for specifying CS electrode 3d3 passes through gate circuit 15c contained in the memory chip corresponding to the ID stored in the register labeled register number 3 of ID register 2b, and selects CS switch 16c.

Thus, CS signal wire 17, contained in the memory chip corresponding to the ID stored in the register labeled register number 3 of ID register 2b, can be set such that CS signal wire 17 is applied with the CS signal which is supplied to CS through electrode 3d3.

Next, control circuit 2a6 uses the ID stored in the register labeled register number 4 of ID register 2b to select a memory chip corresponding to this ID. Control circuit 2a6 selects SC switch 16d corresponding to CS through electrode 3d4 of the selected memory chip. Specifically, control circuit 2a6 reads the ID stored in the register labeled register number 4 of ID register 2b, and delivers the read ID to through electrode 3a via output circuit 2a3. In the memory chip having the same ID as the ID stored in the register labeled register number 4 of ID register 2b, comparator 12 delivers the output at “H,” causing gate circuits 15a-15d to open. In this embodiment, this condition is established when control circuit 2a6 has selected a memory chip corresponding to the ID stored in the register labeled register number 4 of ID register 2b.

Subsequently, CS electrode specifier 2c applies a signal for specifying CS electrode 3d4 and that turns on CS switch 16d corresponding to CS through electrode 3d4, to through electrodes for CS electrode specifying signal 3c4. This signal for specifying CS electrode 3d4 passes through gate circuit 15d contained in the memory chip corresponding to the ID stored in the register labeled register number 4 of ID register 2b, and selects CS switch 16d.

Thus, CS signal wire 17, contained in the memory chip corresponding to the ID stored in the register labeled register number 4 of ID register 2b, can be set such that CS signal wire 17 is applied with the CS signal which is supplied to CS through electrode 3d4 (steps 4j-4l).

Next, memory controller 2 validates CS switches 16 of all memory chips 1a-1d. For example, when CS switches 16 are implemented by electric fuses, memory controller 2 activates the electric fuses selected at steps 4j-4l to make permanent connections of CS through electrodes 3d with CS signal wires 17 (step 4m).

With the foregoing processing, memory controller 2 can access any of stacked memory chips 1a-1d which can be distinguished from one another with the CS signal that is delivered to CS through electrodes 3d1-3d4 by CS signal generator 2d.

While the foregoing embodiment has been described in connection with four stacked memories, the present invention is not limited to the number of stacked chips or functions of the chips.

According to the foregoing embodiment, even if a plurality of semiconductor chips identical in design are connected to one another via their electrodes associated with the same functions, as is the case with the stacked memory in CoC structure, the controller (memory controller) can distinguish the respective semiconductor chips for making access to the intended chip. This is because each semiconductor chip includes an identification information generator (ID generator circuit).

Also, the respective identification information generators can generate different identification information for the semiconductor chips associated therewith, respectively, even though they are identical in design. Because the respective identification information generators generate the identification information using self-running oscillators which have different oscillation periods due to variations in the process for manufacturing the respective semiconductor chips, the difference in oscillation period is increased.

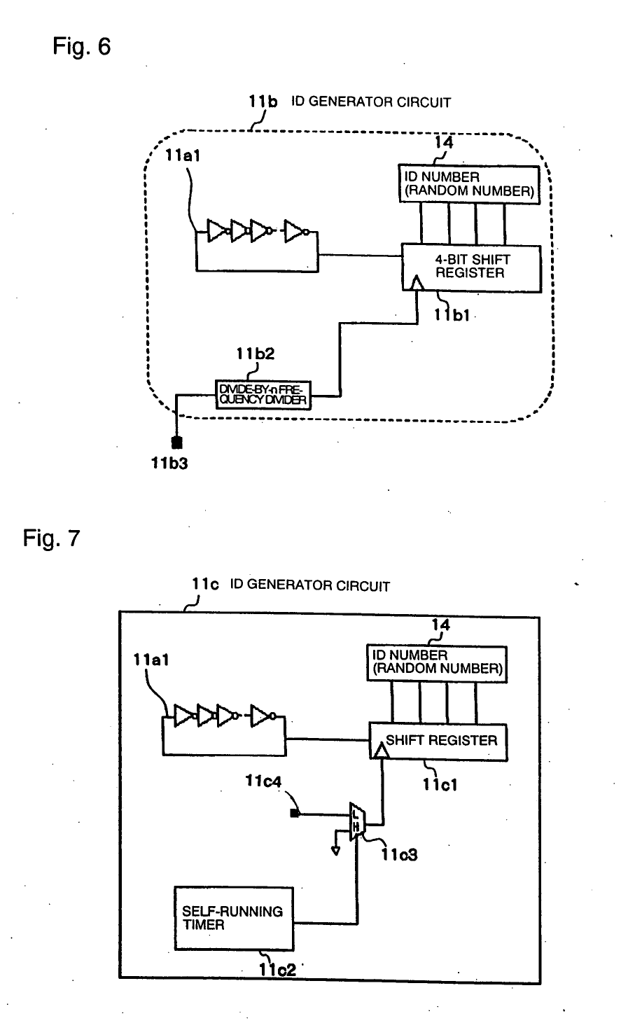

FIG. 6 is a block diagram illustrating the second embodiment of ID generator circuit 11 shown in FIGS. 2 and 4. In FIG. 6, components identical to those in FIG. 3 are designated with the same reference numerals.

In FIG. 6, ID generator circuit 11b includes ring oscillator 11a1, 4-bit shift register 11b1, and divide-by-n divider 11b2.

Shift register 11b1 sequentially samples the output of ring oscillator 11a1 at an output timing of divide-by-n divider 11b2, i.e., at an output timing at which divider 11b2 delivers external clock 11b3 divided by n. Shift register 11b1 stops sampling when it accumulates four bits of the output of ring oscillator 11a1. ID generator circuit 11b uses 4-bit data of shift register 11b1 as the ID.

ID generator circuit 11b eliminates a selector that was needed by ID generator circuit 11a shown in FIG. 3. For this reason, ID generator circuit 11b can be simplified in configuration as compared with ID generator circuit 11a.

FIG. 7 is a block diagram illustrating the third embodiment of ID generator circuit 11 shown in FIGS. 2 and 4. In FIG. 7, components identical to those in FIG. 3 are designated with the same reference numerals.

In FIG. 7, ID generator circuit 11c includes ring oscillator 11a1, 4-bit shift register 11c1, self-running timer 11c2, and selector 11c3.

Self-running timer 11c2 generates a time-up signal when a time period of 1 ms to 1 s has elapsed. Shift register 11c1 sequentially samples the output of ring oscillator 11a1 with internal clock 11c4 delivered from selector 11c3.

When selector 11c3 stops internal clock 11c4 at a timing at which self-running timer 11c2 delivers the time-up signal, shift register 11c1 stops sampling. ID generator circuit 11c uses the 4-bit data of shift register 11c1 as the ID.

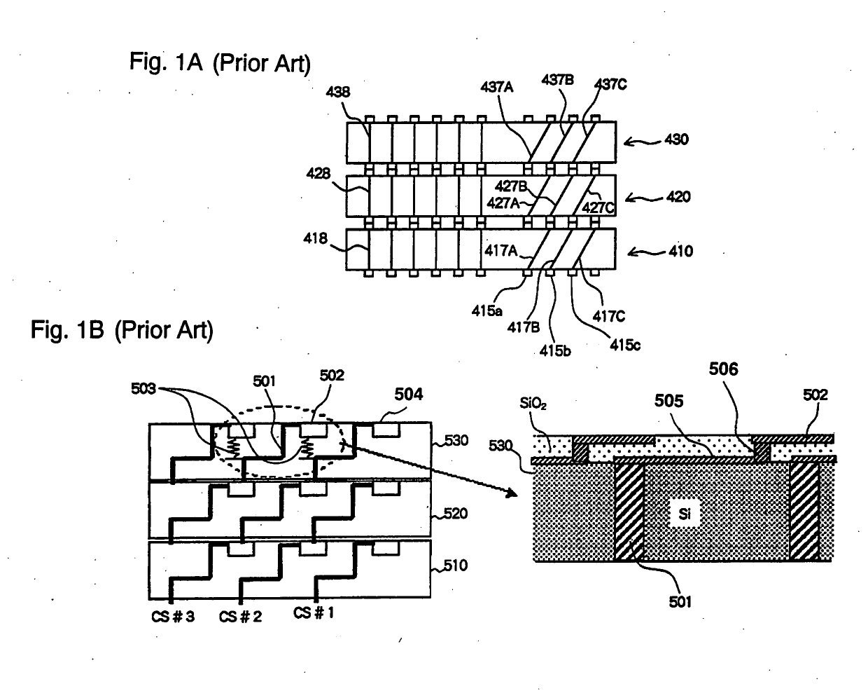

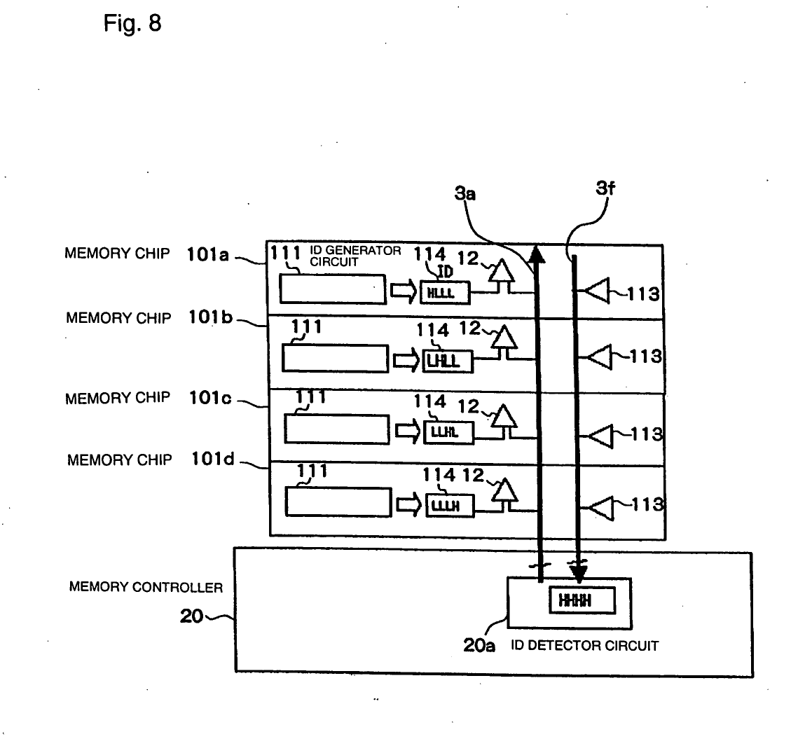

FIG. 8 is an explanatory diagram illustrating the basic configuration of the second embodiment of the semiconductor memory device according to the present invention. In FIG. 8, components identical to those in FIG. 1 are designated with the same reference numerals.

In FIG. 8, the semiconductor memory device includes memory chips 101a-101d, and memory controller 20. Memory chips 101a-101d are examples of semiconductor chips. The semiconductor chips are not limited to memory chips but may be changed as appropriate. Memory controller 20 is an example of a controller.

Memory chips 101a-101d are stacked one upon another. The number of memory chips is not limited to four but may be changed as appropriate. Also, memory chips 101a-101d may or may not be stacked on memory controller 20.

Each of memory chips 101a-101d is formed in a common design. Therefore, circuits formed on respective memory chips 101a-101d are identical in design. Also, the circuits formed on respective memory chips 101a-101d are identical in layout. Further, the wires routed on respective memory chips 101a-101d are identical in design. In other words, in this embodiment, the design concept is such that modification of the pattern of memory chip is not dependent on the order in which the memory chip is stacked.

Each of memory chips 101a-101d is formed with through electrode 3 at the same locations on the memory chip. In this embodiment, each of memory chips 101a-101d is formed with a plurality of through electrodes 3.

Through electrodes 3 are electrically connected to through electrodes 3 on the memory chips stacked above and/or below the associated memory chips. A plurality of electrically connected through electrodes 3 form a through electrode bus. The through electrode bus is electrically connected to memory controller 20.

In this embodiment, through electrode 3a and through electrode 3f are used as through electrodes 3. Through electrode 3a receives an ID signal delivered from memory controller 20. Through electrode 3f receives an ID notification signal (ID) delivered from each of memory chips 101a-101d.

The same number of through electrodes 3f are provided as the number of bits which make up each ID notification signal (ID). Through electrodes 3f are supplied with bit data that has the same digits as each ID notification signal (ID).

Each of memory chips 101a-101d includes ID generator circuit 111, comparator 12, and ID signal generator circuit 113.

ID generator circuit 111 generates the ID (identification information indicative of itself) of the memory chip on which ID generator circuit 111 is disposed. Specifically, ID generator circuit 111 generates ID 114 in accordance with its manufacturing process.

This permits respective ID generator circuits 111 to generate different IDs 114 from one another, even if ID generator circuits 111 are identical in design, relying on variations in the process of respective ID generator circuits 121, and further relying on variations in the process of respective semiconductor chips 101a-101d. ID 114 is n-bit data (where n 2 number of stacked memories). ID 114 is in such a format that only one bit of n bits is at “H” and the remaining bits are at “L” (“H” and “L” may be reverse).

Each of memory chips 101a-101d has n ID signal output through electrodes that serve as through electrodes 3f. Each of memory chips 101a-101d delivers one bit of ID 114 to one ID signal output through electrode 3f. Thus, each of memory chips 101a-101d delivers n-bit ID 114 in parallel using n ID signal output through electrodes 3f. It should be noted that n ID signal output through electrodes 3f correspond bit-by-bit to n-bit ID 114.

As an ID generation start signal is supplied from memory controller 20 to each of memory chips 101a-101d, each of memory chops 101a-101d generates ID 114. Then, each of memory chips 101a-101d simultaneously deliver an “L” signal to ID signal output through electrode 3f corresponding to the “H” bit of ID 114 generated thereby.

Memory controller 20 includes ID detector circuit 20a. ID detector circuit 20a receives n-bit data via ID signal output through electrode bus 3f. ID detector circuit 20a counts the number of bits at “L” within the n-bit data. ID detector circuit 20a determines that the ID has been uniquely determined when the number of bits at “L” matches the number of stacked memories.

On the other hand, when the number of bits at “L” does not match the number of stacked memories, memory controller 20 (ID detector circuit 20a) supplies the ID generation start signal to each ID generator circuit 111 to repeat the generation of ID 114.

In this embodiment, when memory controller 20 detects ID 114, memory controller 20 need not attempt all possible combinations of IDs generated by ID generator circuit 111, as is required in the first embodiment illustrated in FIG. 4. Consequently, memory controller 20 can detect the ID in a shorter time.

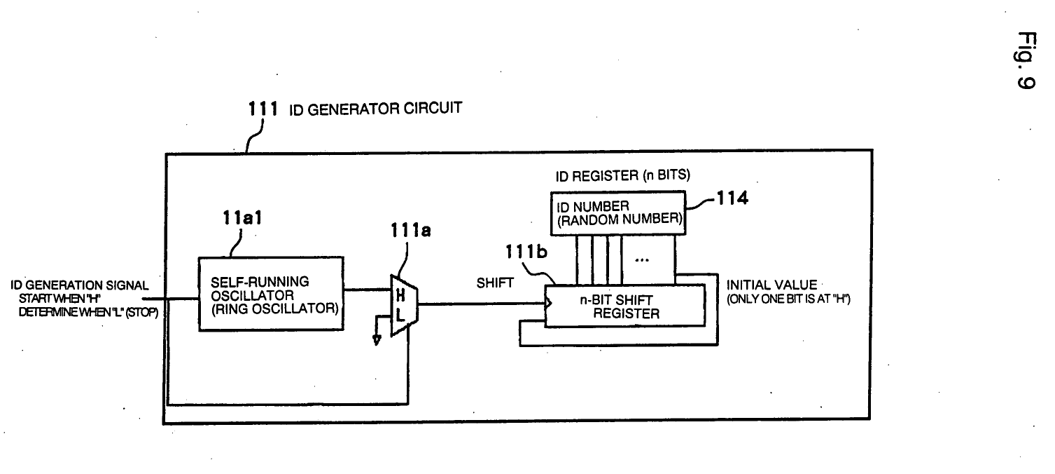

FIG. 9 is a block diagram illustrating one embodiment of ID generator 111 shown in FIG. 8. In FIG. 9, components identical to those in FIGS. 8 and 3 are designated with the same reference numerals.

In FIG. 9, ID generator circuit 111 includes ring oscillator 11a1, selector 111a, and n-bit shift register 111b.

The output of ring oscillator 11a1 is applied to the clock input terminal of shift register 111b via selector 111a. An initial value for shift register 111b is a value having “H” only at one digit, for example, “LLL . . . H.” The rear end output of shift register 111b is connected to front end output of shift register 111a. The pulse generated by ring oscillator 11a1 shifts the bit pattern of shift register 111b. Thus, the bit pattern of shift register 111b changes such that the position of “H” moves from the front end of the bit pattern to the rear end of the bit pattern. The rear end output of shift register 111b is returned to the front end input of shift register 111b. Therefore, “H” which has reached the rear end of the bit pattern of shift register 111b is returned to the front end of the bit pattern.

Selector 111a selects and delivers one of the output of ring oscillator 11a1 and an “L” signal. Selector 111a selects the “L” signal when shift register 111b is stopped, and delivers the selected “L” signal.

ID generator circuit 111 generates ID 114 that is the bit pattern of shift register 111b when shift register 111b is stopped.

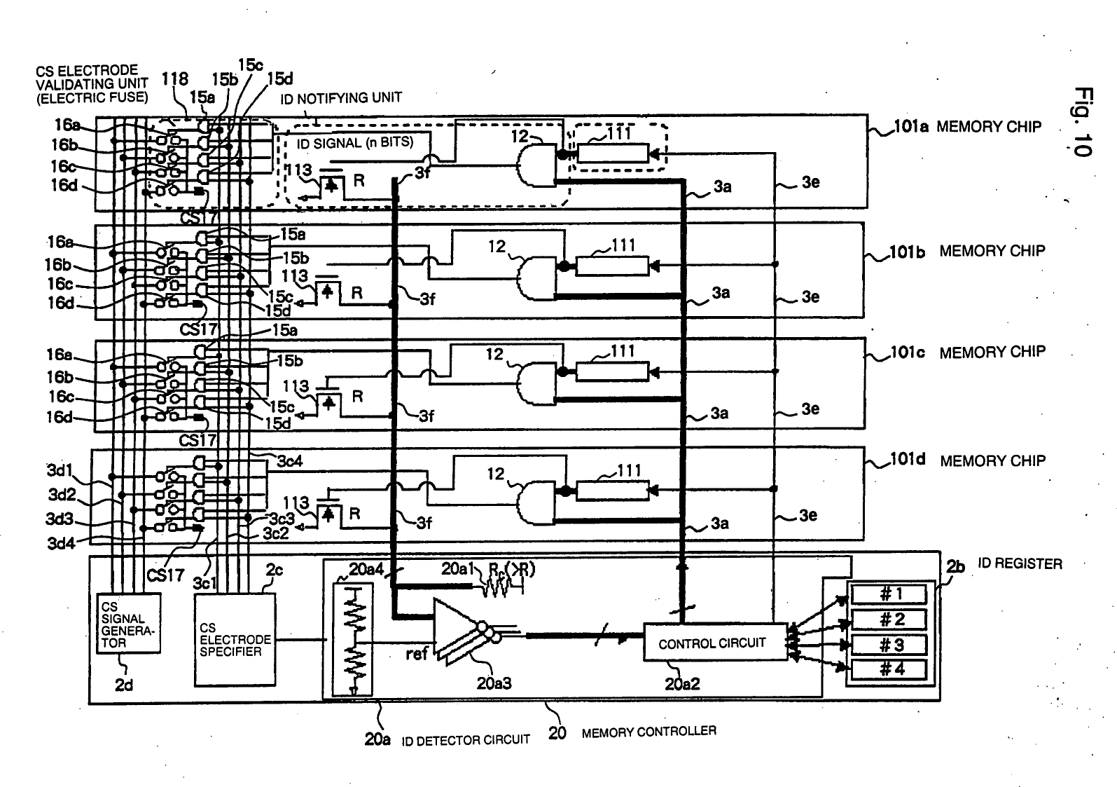

FIG. 10 is a circuit diagram representing the second embodiment of the semiconductor memory device illustrated in FIG. 8. In FIG. 10, components identical to those in FIGS. 4 and 8 are designated with the same reference numerals.

In FIG. 10, each of memory chips 101a-101d include ID generator circuit 111, comparator 12, n ID signal supply circuits 113, gate circuits 15a-15d, CS switches 16a-16d, CS signal wire 17, through electrode (through electrode bus) 3a, through electrodes 3c1-3c4 for CS electrode specifying signal, through electrode 3e for ID generation start signal, and n through electrodes (through electrode bus) 3f.

Each of memory chips 101a-101d also include CS electrode validating unit 118 for validating CS switches 16a-16d. CS switches 16a-16d may be implemented, for example, by electric fuses, or the like. Since memory chips 101a-101d are identical in design, the following description will focus on memory chip 101a, with omission of description of memory chips 101b-101d.

Comparator 12 compares an ID signal that is provided from through electrode 3a with ID 114 generated by ID generator circuit 111.

Each of n ID signal supply circuits 113 comprise an open drain type transistor. Each of ID signal supply circuits 113 is connected to each of n pull-up resistors 20a1 via ID signal output through electrode 3f. The output of each ID signal supply circuit 113 is connected to each of ID signal output through electrodes 3f. Each of ID signal output through electrodes 3f in turn is connected to each of ID signal supply circuits 113. Thus, wired OR logic is made up of the output of ID signal supply circuit 113 and the outputs of ID signal supply circuits 113 of the other memory chips.

As a CS signal is applied from memory controller 20 to CS signal wire 17 via CS through electrode 3d and CS switch 16, this causes activation of the memory chip which contains CS signal wire 17 that has been applied with the CS signal.

Memory controller 20 includes ID detector circuit 20a, ID register 2b, CS electrode specifier 2c, and CS signal generator 2d. ID detector circuit 20a includes n pull-up resistors 20a1, control circuit 20a2, n comparators 20a3, and reference voltage generator 20a4.

Control circuit 20a2 provides an ID generation start signal to each memory chip 101a-101d, specifically, to each ID generator circuit 111 via through electrode 3e. Each ID generator circuit 111 generates an n-bit ID upon receipt of the ID generation start signal.

The n-bit ID generated by ID generator circuit 111 is outputted bit-by-bit in parallel to n through electrodes 3f via ID signal supply circuits 113. In n through electrodes (through electrode buses) 3f, “L” is delivered only from through electrode (through electrode bus) 3f that corresponds to the “H” bit in the ID of each memory chip 101a-101d.

It should be noted that in this embodiment, ID signal supply circuit 113 and pull-up resistor 2a1 are placed in a relationship represented by R<Rc, where R is the output resistance of ID signal supply circuit 113, and Rc is the resistance of pull-up resistor.

The n-bit signal (ID notification signal) applied to memory controller 20 via n through electrodes 3f is judged bit-by-bit by comparators 20a3 associated therewith. Each comparator 20a3 is applied with voltage Vref, which is one-half of the pull-up voltage, from reference signal generator 20a4 as a logical threshold voltage. When voltage at one bit of the ID notification signal applied via through electrode 3f is lower than voltage Vref, each comparator 20a3 determines that an “H” bit in the ID of any memory chip is located at a bit that corresponds to that through electrode 3f.

Control circuit 20a2 confirms whether or not the total number of bits, which are determined to be at “H” by comparator 20a3, are equal to the number of stacked memory chips (here, “4”). If the total number of bits is equal to the number of stacked memory chips, then all memory chips 101a-101d have acquired IDs which are different from one another. Thus, control circuit 20a2 completes the detection of the ID for each of memory chips 101a-101d.

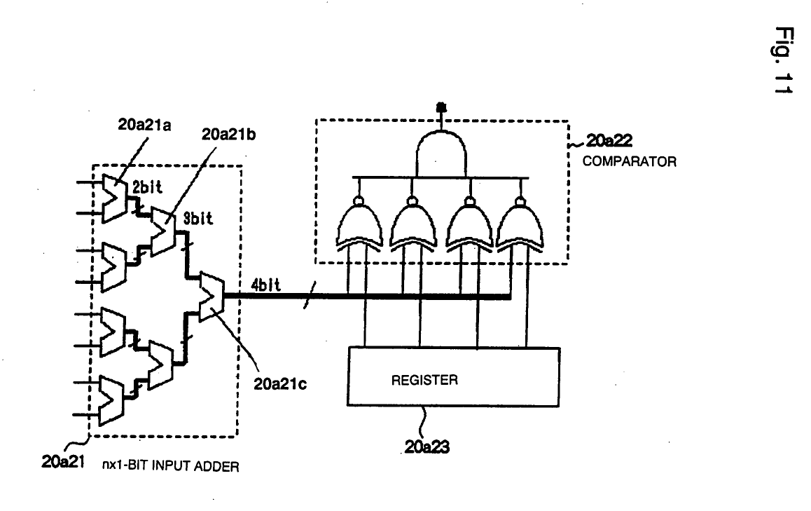

FIG. 11 illustrates an exemplary ID detection completion determining circuit, which determines whether or not the total number of “H” bits is equal to the number of stacked memory chips. The following embodiment will describe n=8. In FIG. 11, the ID detection completion determining circuit is included in control circuit 20a2.

The ID detection completion determining circuit includes n×1-bit (=1 bit×n terms) adder 20a21, and n-bit comparator 20a22. N×1-bit adder 20a21 includes 1-bit adder 20a21a, 2-bit adder 20a21b, and 3-bit adder 20a21c. N×1-bit adder 20a21 adds up respective bits of the ID notification signals (ID) to generate the total number of “H” bits.

Comparator 20a22 compares the output of n×1-bit adder 20a21 with the number of stacked memory chips that have been previously set in register 20a23. Comparator 20a22 delivers “H” when the output of n×1-bit adder 20a21 matches the number of stacked memory chips.

In this way, the ID detection completion determining circuit determines whether the total number of “H” bits is equal to the number of stacked memory chips in this embodiment.

Turning back to FIG. 10, upon completion of the detection of the IDs for all memory chips 101a-101d, memory controller 20 selects CS switches 16 for respective memory chips 10a-101d such that the same CS switch 16 is not selected for two or more of memory chips 101a-101d, and validates the selected CS switches. Electric fuses or latch circuits can implement CS switches 16.

When a memory chip is tested alone before it is stacked, the foregoing embodiment is preferably modified in the following manner.

A default electrode (for example, CS through electrode 3d1) is set as a CS electrode (CS through electrode) of a single memory chip such that the memory chip can be used alone. The memory chip is designed such that it is activated when a CS signal is applied to the default electrode (see FIG. 17).

Each ID generator circuit 111 has a predetermined initial value such as “LLL . . . HL” or “LLL . . . LLH” or the like as the ID. It should therefore be understood that when the ID is directly used to access a single memory chip, the initial value might be used as the ID.

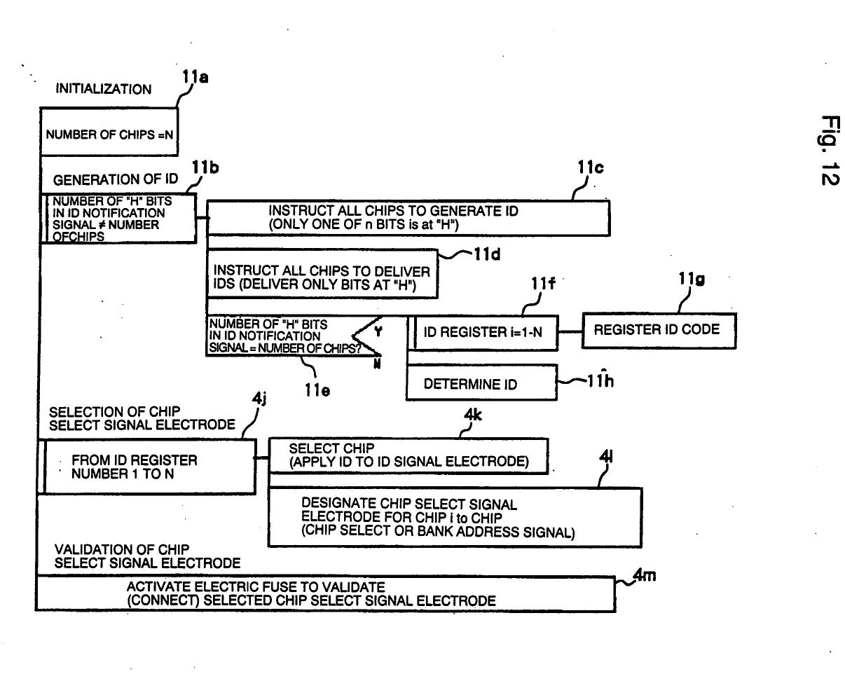

FIG. 12 is a flow chart for describing the operation of the second embodiment of the semiconductor memory device illustrated in FIG. 10. In the following, the operation of the second embodiment of the semiconductor memory device will be described with reference to FIG. 12.

First, memory controller 20, specifically control circuit 20a2, performs initialization for setting the number of stacked memory chips to “4” in a memory (not shown) contained in control circuit 202a (step 11a).

When the number of “H” bits in an ID notification signal is less than “4” which is the number of stacked memory chips, memory controller 20, specifically control circuit 20a2, repeats ID detection processing shown below (step 11b).

Control circuit 20a2 instructs all memory chips 101a-101d to generate IDs (step 11c). Specifically, control circuit 20a2 supplies an ID generation start signal to each ID generator circuit 111. The ID generation start signal is supplied to each ID generator circuit 111 via through electrode 3e. ID generator circuit 111 generates an ID in response to the ID generation start signal applied thereto. It should be noted that the ID generated by each ID generator circuit 111 is n-bit data, only one of which is at “H.”

Each ID generated by each ID generator circuit 111 is added bit-by-bit in through electrode 3f (logical OR operation). Through electrode 3f, which has added each ID, bit by bit, supplies the resulting data to memory controller 20, bit by bit as an ID notification signal (step 11d).

Control circuit 20a2 counts the number of “H” bits in the ID notification signal, and determines whether the counted value matches the number of stacked memory chips (step 11e).

At step 11e, when the counted value matches the number of stacked memory chips, memory controller 20, specifically control circuit 20a2, registers four kinds of IDs (for example, “HLLH,” “LHLL,” “LLHL,” and “LLLH”) one by one in the registers labeled register numbers 1-4 of ID register 2b (steps 11f, 11g, 11h).

At step 11e, when the counted value does not match the number of stacked memory chips, control circuit 20a2 returns the operation to step 11c, and instructs all memory chips 101a-101d to again generate IDs until the number of “H” bits in the ID notification signal matches the number of stacked memory chips.

Control circuit 20a2 proceeds to the next CS validation processing after it has detected IDs for respective memory chips 101a-101d. CS validation processing is similar to the CS validation processing (specifically, steps 4j-4m) shown in FIG. 5.

The foregoing processing enables memory controller 20 to distinguish stacked memory chips 101a-101d from one another with the CS signal applied to CS through electrodes 3d1-3d4 by CS signal supply unit 2d, for access to any of memory chips 101a-101d.

While the foregoing embodiment has been described in connection with a semiconductor memory device comprised of four stacked memory chips, the present invention is not limited in the number of stacked memory chips or function of the chips.

According to the foregoing embodiment, even if a plurality of semiconductor chips identical in design are connected to one another via their electrodes associated with the same functions, as is the case with the stacked memory in CoC structure, the controller (memory controller) can distinguish the respective semiconductor chips for making access to the intended chip. This is because each semiconductor chip includes an identification information generator (ID generator circuit).

Also, the respective identification information generators can generate different identification information for the semiconductor chips associated therewith, respectively, even though they are identical in design. Because the respective identification information generators generate the identification information using self-running oscillators which have different oscillation periods due to variations in the process for manufacturing the respective semiconductor chips, the difference in oscillation period is scaled up.

Further, in the foregoing embodiment, control circuit 20a2 need not generate all possible IDs generated by the memory chips when it attempts to detect IDs for the memory chips.

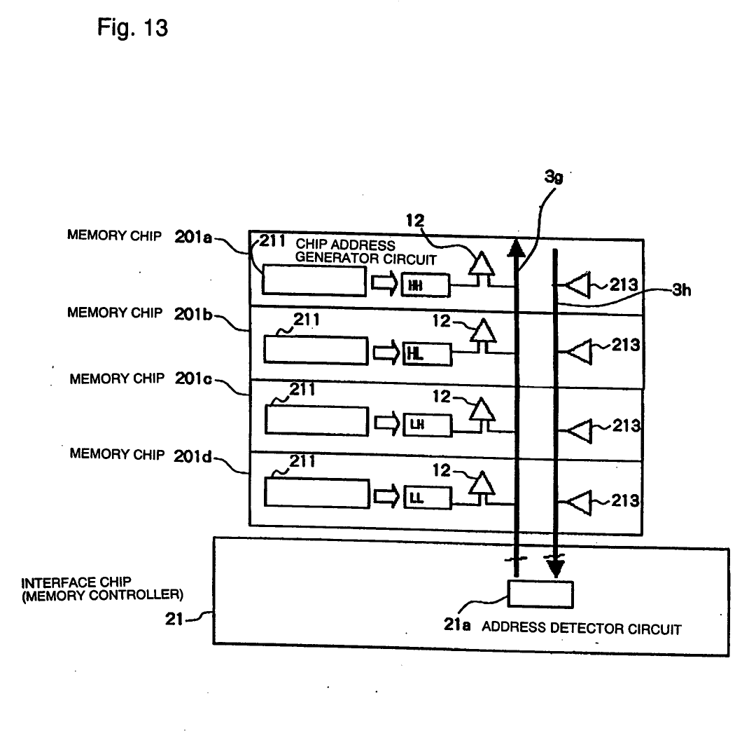

FIG. 13 is an explanatory diagram illustrating the basic configuration of the third embodiment of the semiconductor memory device according to the present invention. In FIG. 13, components identical to those in FIG. 2 or 4 are designated with the same reference numerals.

In FIG. 13, the semiconductor memory device includes memory chips 201a-201d that embody semiconductor chips, and memory controller 21 that embodies a controller. It should be noted that the semiconductor chips are not limited to memory chips, but can be changed as required.

A large difference between the third embodiment illustrated in FIG. 13 and the embodiment illustrated in FIGS. 2 and 4 lies in that the embodiment illustrated in FIG. 13 employs the IDs, which have been used in the embodiment illustrated in FIGS. 2 and 4, as chip addresses.

Therefore, the embodiment illustrated in FIG. 13 can be readily understood by substituting “chip address” for “ID” that is used in the embodiment illustrated in FIGS. 2 and 4.

While FIG. 13 illustrates an example in which the “ID” is replaced with “chip address” in the embodiment illustrated in FIGS. 2 and 4, the third embodiment may be based on the embodiment illustrated in FIGS. 8 and 10 with the “ID” being replaced with “chip address.”

Memory chips 201a-201d are stacked one upon another. It should be understood that the number of memories is not limited to four, but can be changed as appropriate. Also, memory chips 201a-201d may or may not be stacked on memory controller 21.

Each of memory chips 201a-201d is formed in a common design. Therefore, circuits formed on respective memory chips 201a-201d are identical in design. Also, the circuits formed on respective memory chips 201a-201d are identical in layout. Further, the wires routed on respective memory chips 201a-201d are identical in design. In other words, in this embodiment, the design concept is such that modification of the pattern of the memory chip is not dependent on the order in which the memory chip is stacked.

Each of memory chips 201a-201d is formed with through electrodes 3 at the same locations on the memory chip. In this embodiment, each of memory chips 201a-201d is formed with a plurality of through electrodes 3.

Through electrodes 3 are electrically connected to throughhole electrodes 3 formed on the memory chips stacked above and/or below the associated memory chips. A plurality of electrically connected through electrodes 3 form a through electrode bus. The through electrode bus is electrically connected to memory controller 21.

In this embodiment, through electrode (through electrode bus) 3g and through electrode (through electrode bus) 3h are used as through electrodes 3. Through electrode 3g receives a chip address signal delivered from memory controller 21. Through electrode 3h receives an address match signal delivered from each of memory chips 201a-201d.

Each of memory chips 201a-201d includes chip address generator circuit 211, comparator 12, and address match signal output circuit 213.

Chip address generator circuit 211 is identical in configuration to ID generator circuit 11 shown in FIG. 2. Chip address generator circuit 211 uses a generated ID as a chip address.

Memory controller 21 includes an address detector circuit 21a. Address detector circuit 21a detects the chip address of each of memory chips 201a-201d.

In this embodiment, ID generator circuit 11 shown in FIG. 2 is replaced with chip address generator circuit 211; ID match signal supply circuit 13 is replaced with address match signal supply circuit 213; through electrode bus 3a is replaced with chip address signal input through electrode bus 3g; through electrode bus 3b is replaced with through electrodes (through electrode bus) 3h which are applied with an address match signal; and ID detector circuit 2a is replaced with address detector circuit 21a.

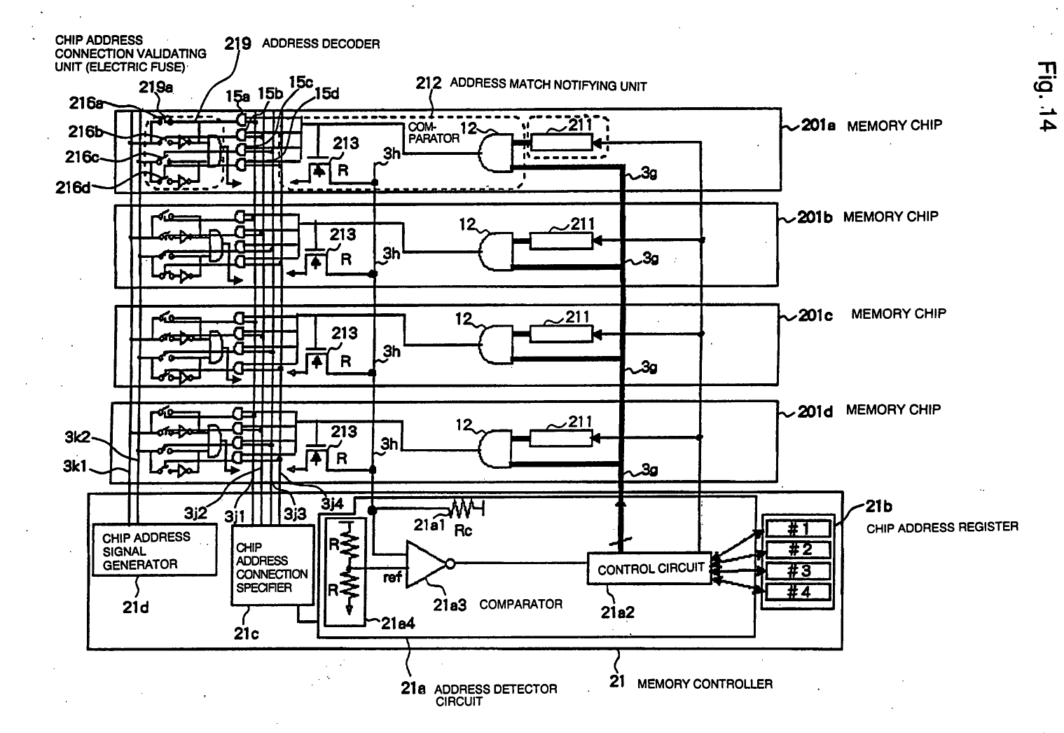

FIG. 14 is a circuit diagram representing the third embodiment of the semiconductor memory device illustrated in FIG. 13. In FIG. 14, components identical to those shown in FIG. 13 are designated with the same reference numerals.

Like FIG. 4, four memory chips 201a-201d are stacked one upon another in FIG. 14. The ID generated by chip address generator circuit 211 is used as a chip address.

CS electrode validating unit 18 (CS switch 16) shown in FIG. 4 is replaced with chip address electrode validating unit 219a within address decoder 219.

In CS electrode validating unit 18 (CS switch 16), one bit of 4-bit CS through electrodes 3d (one CS through electrode 3d) is connected to CS signal wire 17 using an electric fuse or the like in each of the memory chips.

However, chip address electrode validating unit 219a comprises an electric fuse set in address decoder 219 such that address decoder 219 acts (for example, generates a selection output) when a chip address signal, corresponding to a chip address generated by chip address generator circuit 211, is delivered from chip address signal supply unit 21d.

In FIG. 14, each of memory chips 201a-201d includes chip address generator circuit 211, address match notifying unit 212, gate circuits 15a-15d, address decoder 219, through electrode 3g, through electrode 3h, through electrode 3i for chip address generation signal, through electrodes 3j1-3j4 for specifying a chip address connection, and chip address through electrodes 3k1, 3k2.

Address match notifying unit 212 includes comparator 12, and match signal supply circuit 213. Address decoder 219 includes chip address switches 216a-216d.

Memory controller 21 includes address detector circuit 21a, chip address register 21b, chip address connection setting unit 21c which serves as a setting unit, and chip address signal supply unit 21d.

Address detector circuit 21a detects chip addresses given to memory chips 201a-201d, and stores found chip addresses in chip address register 21b.

Address detector circuit 21a includes pull-up resistor 21a1, control circuit 21a2, comparator 21a3, and reference voltage generator 21a4.

Control circuit 21a2 provides a chip address generation signal to each of memory chips 201a-201d, specifically, to each chip address generator circuit 211 via through electrode 3i.

Each chip address generator 211 generates a chip address in response to the chip address generation signal received thereby. In this embodiment, the chip address is assumed to have four bits.

Control circuit 21a2 also provides 4-bit signals from “LLLL” to “HHHH” one by one in sequence from through electrode 3g to each of memory chips 201a-201d as chip address signals.

Each of memory chips 201a-201d, specifically each comparator 12, generates a match signal when its own chip address matches a chip address signal supplied from through electrode 3g.

Each match signal supply circuit 213 delivers an address match signal to through electrode 3h when comparator 12 delivers the match signal.

In this embodiment, match signal generator circuit 213 and pull-up resistor 21a1 are set to satisfy the relationship represented by R<Rc, where R is the output resistance of match signal generator circuit 213, and Rc is the resistance of pull-up resistor 21a1.

Comparator 21a3 compares a voltage on through electrode 3h with voltage ref (one half of the pull-up voltage) generated by reference voltage generator 21a4 to detect whether an address match signal is supplied to through electrode 3h. Specifically, comparator 21a3 determines that the address signal is supplied to through electrode 3h when the voltage on through electrode 3h is lower than voltage ref. In other words, comparator 21a3 determines that the chip address signal “matches” the chip address of any memory chip when the voltage on through electrode 3h is lower than voltage ref.

When comparator 21a3 detects that the address match signal is supplied to through electrode 3h, control circuit 21a2 stores the chip address signal at that time in chip address register 21b. Therefore, chip address register 21b stores the chip addresses of memory chips 201a-201d.

Chip address connection specifier 21c is connected to through electrodes 3j1-3j4 for specifying a chip address connection. Chip address connection specifier 21c supplies a chip address connection specifying signal to through electrodes 3j1-3j4 for specifying the chip address connection to specify arbitrary chip address switch 216 from among chip address switches 216a-216d.

Specifically, memory controller 21 sequentially provides the chip addresses stored in chip address register 21b to through electrode 3g. Further, in concert with the provision of the chip addresses, memory controller 21 supplies the chip address connection specifying signal from chip address connection specifier 21c to through electrodes 3j1-3j4 in sequence for specifying a chip address connection. With this operation, memory controller 21 specifies arbitrary chip address switch 216 from among chip address switches 216a-216d.

Electric fuses or latch circuits can implement chip address switches 216.

When a memory chip is tested alone before it is stacked, the foregoing embodiment is preferably modified in the following manner.

A default value (for example, “LL”) is set as a chip address of a single memory chip such that the memory chip can be used alone. The memory chip is designed such that the memory chip is activated when the default chip address is applied thereto.

According to this embodiment, the stacked semiconductor chips can be distinguished from one another for access to an intended semiconductor chip that used the chip address generated by that semiconductor chip.

While the respective embodiments have been described in connection with examples in which the present invention is applied to implementations of the CoC structure having through electrodes, the present invention, however, is not limited to such a CoC structure having through electrodes. For example, the present invention can be applied as well to a stack package or the like, as described below.

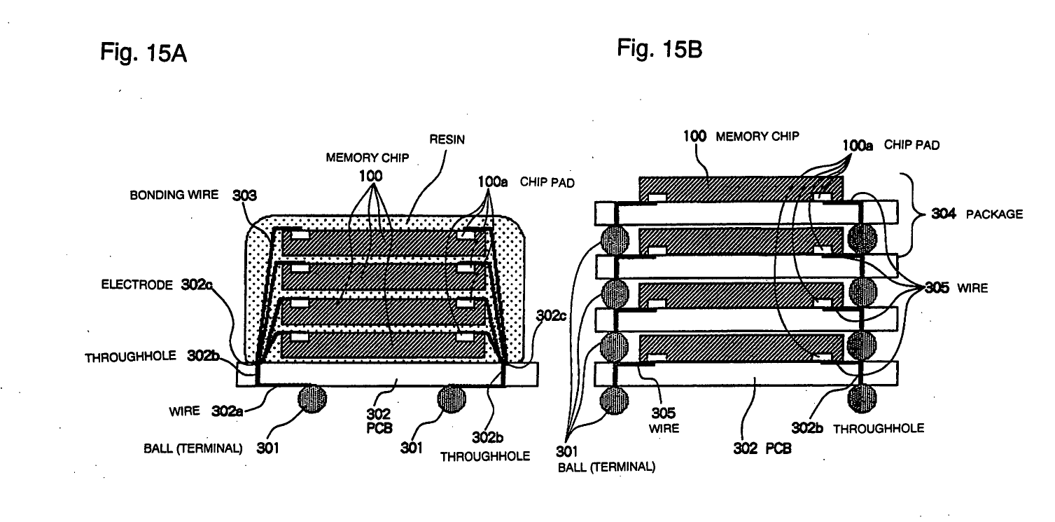

A stack package illustrated in FIG. 15a has memory chips 100 stacked on PCB board 302 that has ball terminals 301. Each memory chip 100 is provided with chip pads 100a. Ball terminals 301 are each connected to a wire and electrode 302c on the surface of PCB board 302 via PCB wire 302a and throughhole 302b. Bonding wire 303 connects electrode 302c to each chip pad 100a. Chip pads 100a have the same function.

A stack package illustrated in FIG. 15b has packages 304 stacked one upon another. Each package 304 comprises PCB board 302 having ball terminals 201, and memory chip 100 mounted on PCB board 302. Each memory chip 100 has chip pads 100a that are identical in function. Each PCB board 302 has throughholes 302b. In this structure, each pad 100a is also connected to common wire 305.

In both FIGS. 15A and 15B, signal wires are commonly connected to stacked memory chips 100. Their electric connections are similar to the through electrodes in CoC structure described in the aforementioned embodiments.

In conclusion, the present invention can also be effectively applied to the stack package as shown in FIGS. 15A and 15B.

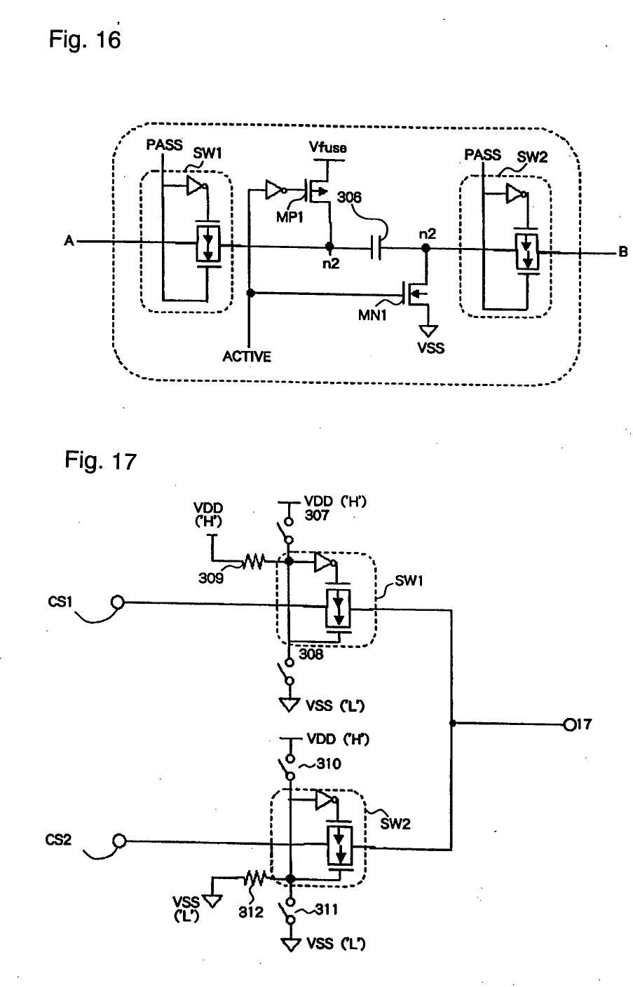

FIG. 16 is a circuit diagram illustrating an exemplary switch comprised of an electric fuse. As can be appreciated, the circuit illustrated in FIG. 16 is an example of CS electrode validating unit 18, CS electrode validating unit 118, and chip address connection validating unit 219a.

Signals, applied to control terminals (specifically, a PASS terminal and an ACTIVE terminal) of an electric fuse switch, are generated from the memory controller. Therefore, it is the memory controller that determines settings for the switch with the electric fuse.

In FIG. 16, capacitor 306 which sandwiches the insulating film is used as an electric fuse between nodes A, B. Between nodes A, B, electric fuse 306 is connected such that it is sandwiched between switches SW1 and SW2 of transfer gate type. Switches SW1, SW2 are normally used in ON state (PASS=“H”). One terminal of electric fuse 306, i.e., node n1, is connected to high voltage power source Vfuse via pMOSMP1, while node n2 is connected to low voltage power source VSS via nMOSMN1.

Electric fuse 306 comprises a capacitor. Thus, a path between nodes n1 and n2 is normally non-conductive. Therefore, even if switches SW1, SW2 are made conductive, the path between nodes n1 and n2 is non-conductive.

To make electrical connections between nodes n1 and n2 using electric fuse 306, switches SW1, SW2 are both turned off (PASS=“L”), while pMOSMP1 and nMOSMN1 are turned on (ACTIVE=“H”). With this operation, the potential at high voltage power source Vfuse is applied to node n1, while the potential at low voltage power source VSS is applied to node n2. Consequently, a high voltage is applied across capacitor 306. This causes the insulating film of capacitor 306 to break down, with the result that capacitor 306 is made conductive.

Subsequently, when the voltage applied to Vfuse is stopped, pMOSMP1 and nMOSMN1 are returned to OFF state (ACTIVE=“L”), and switches SW1, SW2 are again returned to ON state (PASS=“H”), the path between nodes A, B becomes conductive.

With the foregoing operation, the switch is validated with the electric fuse.

FIG. 17 is a circuit diagram representing the main portion of a single memory chip which has a plurality of spare predetermined CS electrodes (CS through electrodes), one of which is made available as a default CS electrode, in order to facilitate individual testing on each of the memory chips before they are stacked.

In the example illustrated in FIG. 17, CS electrode CS1 is electrically connected to CS signal wire 17 when an electric fuse is not activated. It should be noted that for simplifying the description there are two spare CS electrodes CS1, CS2 (CS through electrodes).

Electrode CS1 and electrodes CS2 are both connected to CS signal wire 17 via switches SW1, SW2 of transfer gate type, respectively. A control input of switch SW1 is connected to VDD (“H” level) and VSS (“L” level) via switches 307, 308 of the electric fuse, respectively. The control input of switch SW1 is also connected to VDD (“H” level) through pull-up resistor 309 that has a significantly higher resistance than a conducting electric fuse.

In this way, the control input of switch SW1 is pulled up to “H” through pull-up resistor 309 even when the electric fuse is non-conductive, causing switch SW1 to turn on. Consequently, electrode CS1 is electrically connected to CS signal wire 17.

Conversely, the control input of switch SW2 is pulled down to VSS (“L” level) through pull-down resistor 312, which has a significantly higher resistance than conducting electric fuses 310, 311, causing switch SW2 to turn off to make electrode CS2 and CS signal wire 17 electrically non-conductive.

The resistance of the conductive electric fuse is set lower than those of pull-up resistor 309 and pull-down resistor 312. Thus, the control input of either of switches SW1, SW2 is brought to the “H” or “L” level potential through the conductive electric fuse when the switch of any of the electric fuses on the “H” or “L” side becomes conductive. Thus, switches SW1, SW2 are determined to turn on/off.

When an electric fuse implements CS switch, the following advantages are provided.

Once CS switches are validated (the electric fuses are short-circuited), connections associated with the CS signal are made permanent between memory controller and stacked memory chips. Thus, for example, once processing for detecting the ID of each memory chip 1a-1d (hereinafter called the “ID detection processing”) is performed in a stacked memory assembly step or in a subsequent testing step or the like, the ID detection processing need not be performed again afterwards.

In this embodiment, the control input of switch SW1 is pulled up to “H” level through a resistor having a significantly higher resistance than the conductive electric fuse, while the control input of switch SW2 is pulled down to “L” level through a resistor having a significantly higher resistance than a conductive electric fuse. Therefore, CS1 can be electrically connected to signal wire 17 when the electric fuse is not active. This permits electrode CS1 to be used as a default CS electrode.

While the foregoing embodiment has been described in connection with an example which has two spare CS electrodes, a default CS electrode can be set, as well, using a similar method when there are three or more spare CS electrodes.

Also, it should be understood that when a memory chip is selected with an address signal instead of the CS signal, the default address can be set as well using a similar method.

Each of the foregoing embodiments eliminates the need for obliquely passing through electrodes through stacked semiconductor chips or for forming the blind throughhole structure in the stacked semiconductor chips. This can prevent a complicated process.

The present invention can be utilized in such applications as large capacity memories, memory combination chips, mixed memory packages, and the like, when memory chips are stacked to implement the semiconductor device. Further, such semiconductor memory devices can be utilized in such applications as personal computers (PC), mobile telephones, and small digital home electric appliances.

While preferred embodiments of the present invention have been described using specific terms, such description is for illustrative purposes only, and it is to be understood that changes and variations may be made without departing from the spirit or scope of the following claims.

1. A semiconductor device comprising:
a plurality of semiconductor chips;
an identification information generator associated with each of said plurality of semiconductor chips, for generating identification information in accordance with a manufacturing process of said associated semiconductor chip; and
a controller for detecting the identification information generated by said identification information generator to control each of said plurality of semiconductor chips based on the detected identification information.

2. The semiconductor device according to claim 1, wherein:
said controller generates a plurality of chip select signals for alternatively selecting said plurality of semiconductor chips,
each of said plurality of semiconductor chips includes a chip select signal receiver which can be set to accept any of said plurality of chip select signals, and
said controller includes:
a setting unit for setting said chip select signal receiver based on said identification information such that said chip select signal receiver accepts a chip select signal for selecting a semiconductor chip which includes said chip select signal receiver; and
a semiconductor chip controller for controlling each of said plurality of semiconductor chips based on said chip select signal.

3. The semiconductor device according to claim 2, wherein said chip select signal receiver is previously set to accept a particular chip select signal.

4. The semiconductor device according to claim 2, wherein:
said chip select signal receiver includes a switch, and
said setting unit sets said switch based on said identification information such that said chip select signal receiver accepts a chip select signal for selecting a semiconductor chip which includes said chip select signal receiver.

5. The semiconductor device according to claim 2, wherein:
said chip select signal receiver includes a fuse, and
said setting unit sets said fuse based on said identification information such that said chip select signal receiver accepts a chip select signal for selecting a semiconductor chip which includes said chip select signal receiver.

6. The semiconductor device according to claim 1, wherein:
each of said plurality of semiconductor chip uses its identification information as its chip address, and
said controller detects the chip address of each of said plurality of semiconductor chips, and controls each of said plurality of semiconductor chips based on the detected chip address.

7. The semiconductor device according to claim 6, wherein:
said controller generates a plurality of chip address signals for alternatively selecting said plurality of semiconductor chips,
each of said plurality of semiconductor chips includes a chip address signal receiver which can be set to accept any of said plurality of chip address signals, and
said controller includes:
a setting unit for setting said chip address signal receiver based on said identification information such that said chip address signal receiver accepts a chip address signal for selecting a semiconductor chip which includes said chip address signal receiver; and
a semiconductor chip controller for controlling each of said plurality of semiconductor chips based on said chip address signal.

8. The semiconductor device according to claim 7, wherein said chip address signal receiver is previously set to accept a particular chip address signal.

9. The semiconductor device according to claim 7, wherein:
said chip address signal receiver includes a switch, and
said setting unit controls said switch based on said identification information for setting said switch such that said chip address signal receiver accepts a chip address signal for selecting a semiconductor chip which includes said chip address signal receiver.

10. The semiconductor device according to claim 7, wherein:
said chip address signal receiver includes a fuse, and
said setting unit sets said fuse based on said identification information such that said chip address signal receiver accepts a chip address signal for selecting a semiconductor chip which includes said chip address signal receiver.

11. The semiconductor device according to claim 1, wherein:
said plurality of semiconductor chips are interconnected by through electrodes which extend through said plurality of semiconductor chips; and
said controller provides a common signal to said plurality of semiconductor chips via said through electrode.

12. The semiconductor device according to claim 1, wherein:
said plurality of semiconductor chips are interconnected by bonding wires, and
said controller provides a common signal to said plurality of semiconductor chips via said bonding wire.

13. The semiconductor device according to claim 1, wherein said plurality of semiconductor chips make up packages together with boards on which said plurality of semiconductor chips are separately disposed, and said packages are stacked one upon another.

14. The semiconductor device according to claim 1, wherein said identification information generator includes:
a self-running oscillator; and
an identification information generator circuit for generating said identification information based on an output of said self-running oscillator.

15. The semiconductor device according to claim 14, wherein said identification information generator circuit comprises a counter for counting pulses generated by said self-running oscillator for a predetermined period of time, and delivering the counted value as said identification information.

16. The semiconductor device according to claim 15, wherein:
said identification information generator circuit further includes a timer for measuring the predetermined period of time, and
said counter counts said pulses for the predetermined period of time based on the measured result of said timer.

17. The semiconductor device according to claim 16, wherein said timer divides a frequency of an external clock to measure the predetermined period of time.

18. The semiconductor device according to claim 16, wherein said timer is a self-running timer.

19. The semiconductor device according to claim 14, wherein said identification information generator circuit comprises a shift register for sampling pulses generated by said self-running oscillator based on a frequency-divided version of an external clock, and delivers a result of the sampling as said identification information.

20. The semiconductor device according to claim 14, wherein said identification information generator circuit comprises a shift register for circulating n-bit data which includes one bit having a different value from remaining bits for a predetermined period of time based on pulses generated by said self-running oscillator, and delivers a result of a circulation as said identification information.

21. The semiconductor device according to claim 14, wherein said identification information generator has a predetermined initial value.

22. The semiconductor device according to claim 1, wherein each of said plurality of semiconductor chips is a memory chip.

23. The semiconductor device according to claim 1, wherein said plurality of semiconductor chips is stacked one upon another.

24. A semiconductor chip control method performed by a controller for controlling a plurality of semiconductor chips, each of said plurality of semiconductor chips including an identification information generator for generating identification information in accordance with a manufacturing process of each said semiconductor chip, said method comprising the steps of:
detecting the identification information of each of said plurality of semiconductor chips; and
controlling each of said plurality of semiconductor chips based on the detected identification information.

25. The semiconductor chip control method according to claim 24, wherein each of said plurality of semiconductor chips includes a chip select signal receiver which can be set to accept any of a plurality of chip select signals generated by said controller, said method further including the steps of:
setting said chip select signal receiver based on said identification information such that said chip select signal receiver accepts a chip select signal for selecting a semiconductor chip which includes said chip select signal receiver; and
controlling each of said plurality of semiconductor chips based on said chip select signal.

26. The semiconductor chip control method according to claim 24, wherein:
each of said plurality of semiconductor chips uses its identification information as its chip address,
said step of detecting includes detecting the chip address of each of said plurality of semiconductor chips, and
said step of controlling includes controlling each of said plurality of semiconductor chips based on the detected chip address.

27. The semiconductor chip control method according to claim 26, wherein:
each of said plurality of semiconductor chips includes a chip address signal receiver which can be set to accept any of a plurality of chip address signals generated by said controller, said method further including the steps of:
setting said chip address signal receiver based on said identification information such that said chip address signal receiver accepts a chip address signal for selecting a semiconductor chip which includes said chip address signal receiver; and
controlling each of said plurality of semiconductor chips based on said chip address signal.
